(19) United States
(12) Patent Application Publication
(10) Pub. No.: US 2024/0072046 A1
(43) Pub. Date: Feb. 29, 2024

(54) SEMICONDUCTOR STRUCTURE WITH REDUCED PARASITIC CAPACITANCE AND METHOD FOR MANUFACTURING THE SAME

(71) Applicant: Taiwan Semiconductor Manufacturing Company, Ltd., Hsinchu (TW)

(72) Inventors: Cheng-Ting CHUNG, Hsinchu (TW); Li-Zhen YU, Hsinchu (TW); Jin CAI, Hsinchu (TW)

(73) Assignee: Taiwan Semiconductor Manufacturing Company, Ltd., Hsinchu (TW)

(21) Appl. No.: 17/900,001

(22) Filed: Aug. 31, 2022

(51) Int. Cl. H01L 27/088; H01L 21/8234; H01L 29/06; H01L 29/40; H01L 29/423; H01L 29/786

(52) U.S. Cl. CPC H01L 27/088; H01L 21/823412; H01L 29/0673; H01L 29/401; H01L 29/42392; H01L 29/78696

(57) ABSTRACT

A semiconductor structure includes two source/drain features spaced apart from each other, at least one channel feature disposed between the two source/drain features, a gate dielectric layer disposed on the at least one channel feature, a gate feature, and an electrically conductive capping feature. The gate feature is disposed on the gate dielectric layer and has a first surface, a second surface which is opposite to the first surface, and an interconnect surface which interconnects the first and second surfaces. The electrically conductive capping feature is in direct contact with one of the first and second surfaces of the gate feature, and extends beyond the interconnect surface of the gate feature. Methods for manufacturing the semiconductor structure are also disclosed.

### BACKGROUND

Transistors are key active components in modern integrated circuits (ICs). Power-Performance-Area (PPA) are three major indicators (such as power consumption, speed and integration density of the ICs) to characterize ICs fabricated at a certain technology node. With rapid development of semiconductor technology, critical dimension (CD) of transistors keeps shrinking and various three-dimensional (3D) transistor structures are springing up, making it possible to integrate a large number of transistors per unit area. Till date, advanced node 3D ICs with high speed and/or low power consumption are in continuous development to achieve a better PPA.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flow diagram illustrating a method for manufacturing a semiconductor structure in accordance with some embodiments.

FIG. 1B is a continuation of the flow diagram of the method shown in FIG. 1A.

FIGS. 2 to 45 illustrate schematic views of intermediate stages of the method depicted in FIGS. 1A and 1B in accordance with some embodiments.

FIG. 46A is a flow diagram illustrating another method for manufacturing a semiconductor structure in accordance with some embodiments.

FIG. 46B is a continuation of the flow diagram of the method shown in FIG. 46A.

FIGS. 47 to 57 illustrate schematic views of intermediate stages of the method depicted in FIGS. 46A and 46B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, for a transistor including a gate, a source and a drain, the gate is separated from the source and the drain by dielectric material(s). Therefore, a gate-to-source parasitic capacitance (Cgs) and a gate-to-drain parasitic capacitance (Cgd) are inevitably generated, which may adversely affect the switching speed of the transistor. For example, the gate-to-source parasitic capacitance includes a parallel plate capacitance part which is generated between parallel surfaces of the gate and the source that face each other through, for example, a gate dielectric, and a fringing capacitance part which is generated between surfaces of the gate and the source that are not parallel to each other and that face each other through, for example, an interlayer dielectric layer. The present disclosure is directed to a semiconductor structure including a gate having two opposite surfaces which are respectively proximate to a source and a drain, and which have a reduced area, such that the fringing capacitance part between the gate and the source/drain may be significantly reduced. The semiconductor structure may be applied to fin-type FETs (FINFET), multi-gate FETs (e.g., GAA FETs), multi-bridge channel FETs (MBCFET), fork-sheet FETs, etc.), memory cells, inverters, or other suitable devices or applications.

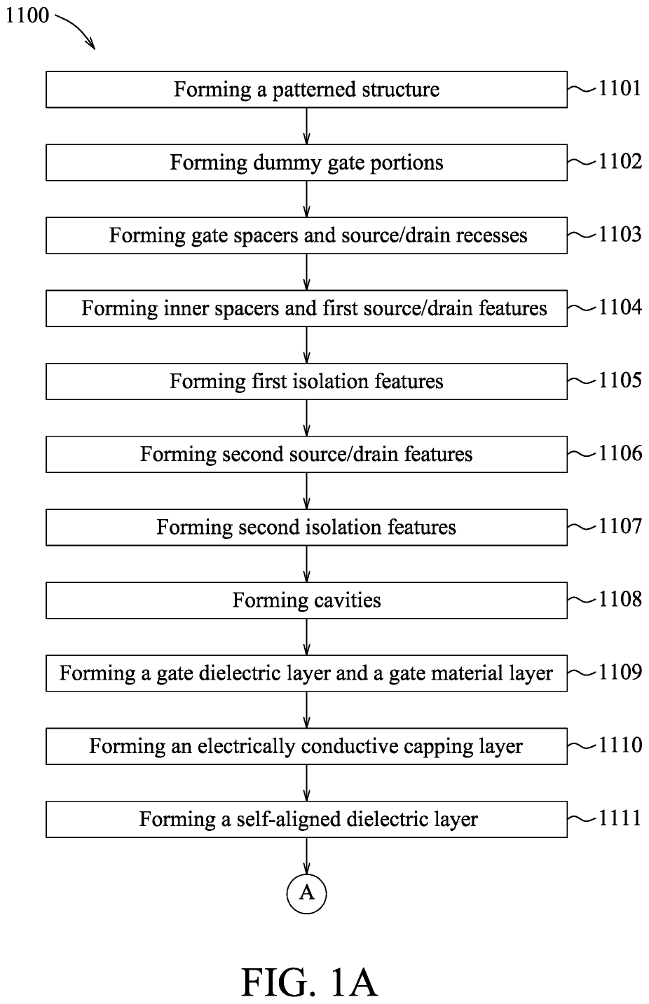

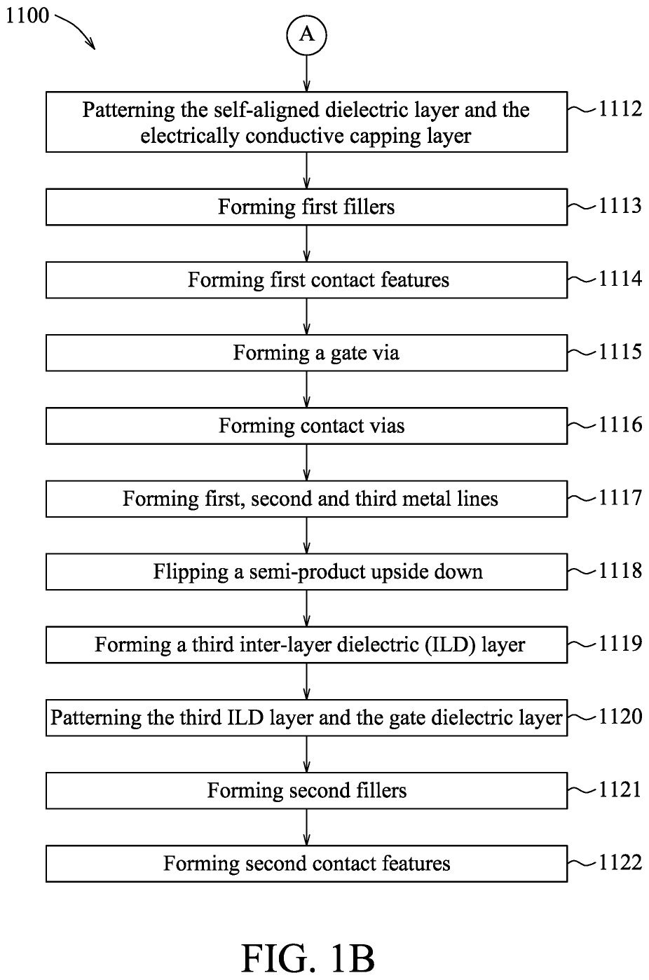

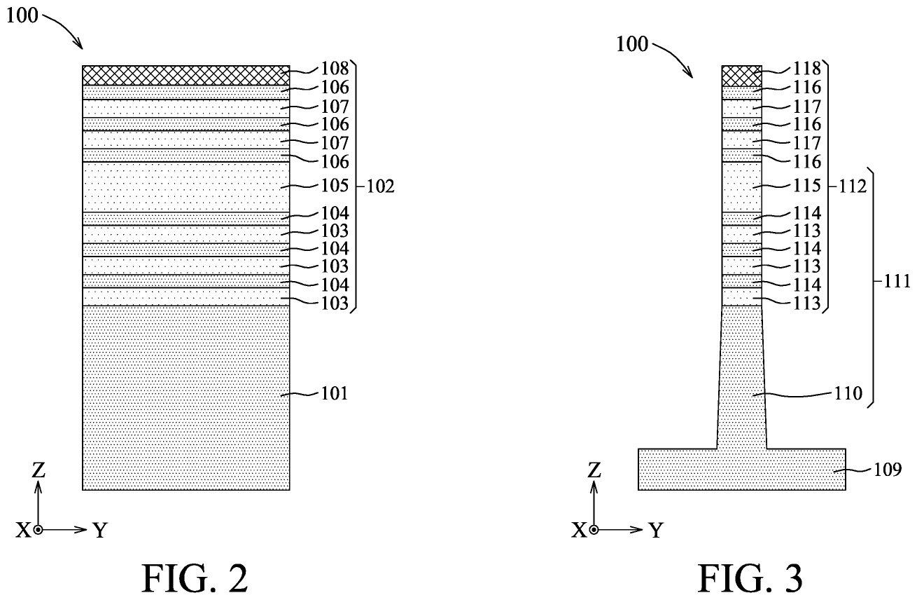

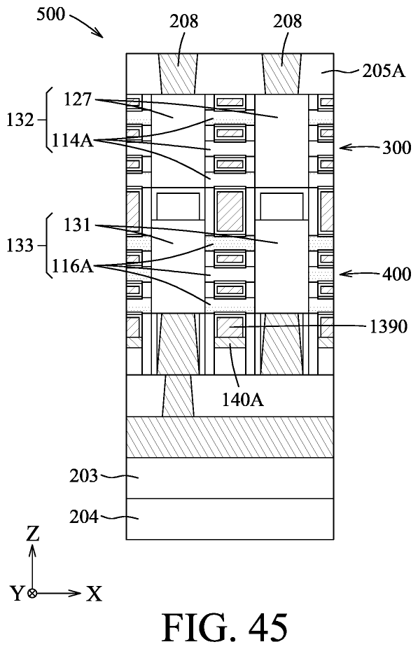

FIGS. 1A and 1B are flow diagrams illustrating a method 1100 for manufacturing a semiconductor structure (for example, a semiconductor structure 500 shown in FIGS. 44 and 45) in accordance with some embodiments. FIGS. 2 to 45 illustrate schematic views of intermediate stages of the method 1100 in accordance with some embodiments. Some repeating structures are omitted in FIGS. 2 to 45 for the sake of brevity.

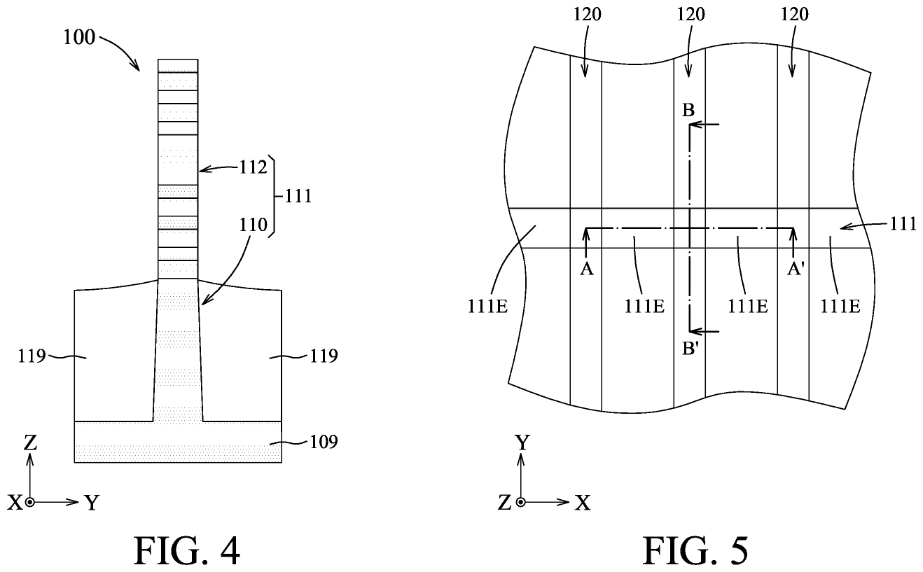

Referring to FIG. 1A and the example illustrated in FIG. 4, the method 1100 begins at step 1101, where a patterned structure 100 is formed. It should be noted that although the method 1100 is exemplified by a method for manufacturing a GAA structure including a plurality of GAA FETs (for example, a first semiconductor device 300 and a second semiconductor device 400 which are stacked on each other as shown in FIG. 45), the method 1100 may be used for manufacturing other suitable structures.

In some embodiments, as shown in FIG. 4, the patterned structure 100 includes a semiconductor substrate 109, a fin structure 111 disposed on the semiconductor substrate 109, and two isolation portions 119 disposed on the semiconductor substrate 109 at two opposite sides of the fin structure 111.

In some embodiments, step 1101 may include sub-steps 1101A to 1101C.

Referring the example illustrated in FIG. 2, in sub-step 1101A, a stack 102 is formed on a starting substrate 101 using chemical vapor deposition (CVD), atomic layer deposition (ALD), or other suitable deposition techniques.

In some embodiments, the starting substrate 101 may be made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The material for forming the starting substrate 101 may be doped with p-type impurities or n-type impurities, or undoped. In addition, the starting substrate 101 may be a bulk silicon substrate, a silicon-on-insulator (SOI) substrate, or a germanium-on-insulator (GOI) substrate. Other suitable materials for the starting substrate 101 are within the contemplated scope of the present disclosure.

In some embodiments, the stack 102 includes at least one first sacrificial layer 103 and at least one first semiconductor layer 104 disposed to alternate with the first sacrificial layer 103 in a Z direction. The at least one first sacrificial layer 103 is disposed between the at least one first semiconductor layer 104 and the starting substrate 101.

In some embodiments, the first semiconductor layer 104 may be made from a material the same as or different from that of the starting substrate 101. In some embodiments, the first sacrificial layer 103 may be made of a material that is different from that of the first semiconductor layer 104, so that the first sacrificial layer 103 and the first semiconductor layer 104 have different etch selectivity and/or oxidation rates. Since suitable materials for the first semiconductor layer 104 and the first sacrificial layer 103 are similar to those for the starting substrate 101, details thereof are omitted for the sake of brevity. In some embodiments, the first semiconductor layer 104 is made of silicon, and the first sacrificial layer 103 is made of silicon germanium. Other materials suitable for the first semiconductor layer 104 and the first sacrificial layer 103 are within the contemplated scope of the present disclosure.

In some embodiments, the stack 102 has a plurality of the first sacrificial layers 103 and a plurality of the first semiconductor layers 104. An uppermost one of the first semiconductor layers 104 is disposed over an uppermost one of the first sacrificial layers 103. The number of the first sacrificial layers 103 and the first semiconductor layer 104 in the stack 102 are determined according to application requirements. In FIG. 2, the stack 102 includes three first sacrificial layers 103 and three first semiconductor layers 104. The first sacrificial layers 103 and the first semiconductor layers 104 may have the same thickness or different thicknesses in the Z direction. In some embodiments, each of the first sacrificial layers 103 may have a thickness ranging from about 8 nm to about 12 nm in the Z direction. In some embodiments, each of the first semiconductor layers 104 may have a thickness ranging from about 4 nm to about 8 nm in the Z direction.

In some embodiments, the stack 102 further includes a second sacrificial layer 105 disposed on the uppermost one of the first semiconductor layers 104, a plurality of second semiconductor layers 106 and a plurality of third sacrificial layers 107 disposed to alternate with the second semiconductor layers 106 in the Z direction. The second semiconductor layers 106 and the third sacrificial layers 107 are disposed on the second sacrificial layer 105. An uppermost one of the second semiconductor layers 106 is disposed over an uppermost one of the third sacrificial layers 107. The number of the third sacrificial layers 107 and the second semiconductor layer 106 in the stack 102 are determined according to application requirements. In FIG. 2, the stack 102 includes two third sacrificial layers 107 and three second semiconductor layers 106.

In some embodiments, each of the second and third sacrificial layers 105, 107 may be made of a material that is the same as that of the first sacrificial layers 103. In some embodiments, the second semiconductor layers 106 may be made of a material that is the same as that of the first semiconductor layers 104. Since suitable materials for the second and third sacrificial layers 105, 107 are similar to those for the first sacrificial layers 103 and suitable materials for the second semiconductor layers 106 are similar to those for the first semiconductor layers 104, details of possible materials for the second and third sacrificial layers 105, 107 and the second semiconductor layers 106 are omitted for the sake of brevity.

In some embodiments, the second sacrificial layer 105 has a thickness greater than that of each of the first and third sacrificial layers 103 and 107. In some embodiments, the second sacrificial layer 105 may have a thickness ranging from about 10 nm to about 50 nm in the Z direction. In some embodiments, the second semiconductor layers 106 may have a thickness the same as that of the first semiconductor layers 104. In some embodiments, the third sacrificial layers 107 may have a thickness the same as that of the first sacrificial layers 103.

In some embodiments, the stack 102 further includes a hard mask layer 108 disposed on the uppermost one of the second semiconductor layers 106. The hard mask layer 108 is provided for forming a patterned hard mask layer 118 (see FIG. 3) so as to protect the underlying materials during an etching process to be subsequently performed. In some embodiments, the hard mask layer 108 may be made of silicon oxide, silicon nitride, silicon oxynitride, or combinations thereof. Other suitable materials for the hard mask layer 108 are within the contemplated scope of the present disclosure.

Referring the example illustrated in FIG. 3, in sub-step 1101B, the starting substrate 101 is patterned into the semiconductor substrate 109 and a lower fin portion 110 of the fin structure 111, and the stack 102 is patterned into an upper fin portion 112 of the fin structure 111 using a patterning process. The upper fin portion 112 includes first sacrificial films 113 obtained by patterning the first sacrificial layers 103, first semiconductor films 114 obtained by patterning the first semiconductor layers 104 and disposed to alternate with the first sacrificial films 113, a second sacrificial film 115 obtained by patterning the second sacrificial layer 105 and disposed on an uppermost one of the first semiconductor films 114, second semiconductor films 116 obtained by patterning the second semiconductor layers 106 and disposed on the second sacrificial film 115, third sacrificial films 117 obtained by patterning the third sacrificial layers 107 and disposed to alternate with the second semiconductor films 116, and the patterned hard mask layer 118 obtained by patterning the hard mask layer 108 and disposed on an uppermost one of the second semiconductor films 116. In some embodiments, the patterning process may include, for example, but not limited to, (i) forming a photoresist on the stack 102 (see FIG. 2), (ii) performing a lithography process to form a patterned photoresist, and then patterning the hard mask layer 108 through the patterned photoresist to form the patterned hard mask layer 118, and (iii) performing an etching process to etch the remaining layers of the stack 102 and the starting substrate 101 through the patterned hard mask layer 118 using, for example, dry etching, wet etching, other suitable etching techniques, or combinations thereof.

Referring the example illustrated in FIG. 4, in sub-step 1101C, the two isolation portions 119 are formed at two opposite sides of the lower fin portion 110 of the fin structure 111. The isolation portions 119 are provided for isolating the fin structure 111 from an adjacent semiconductor structure (not shown). The isolation portions 119 may each be a portion of a shallow trench isolation (STI), a deep trench isolation (DTI), or other suitable structures, and may be made of an oxide material (for example, silicon oxide), a nitride material (for example, silicon nitride), or a combination thereof. Other suitable materials for the isolation portions 119 are within the contemplated scope of the present disclosure. In some embodiments, formation of the isolation portions 119 may include (i) forming an isolation layer over the semiconductor substrate 109 and the fin structure 111 followed by a planarization process, for example, but not limited to, chemical mechanism polishing (CMP), to form isolation regions (not shown) at two opposite sides of the fin structure 111, (ii) recessing the isolation regions to form the isolation portions 119 so as to expose the upper fin portion 112 and an upper part of the lower fin portion 110. It is noted that, the patterned hard mask layer 118 is removed or consumed during formation of the isolation portions 119. Other suitable processes for forming the isolation portions 119 are within the contemplated scope of the present disclosure.

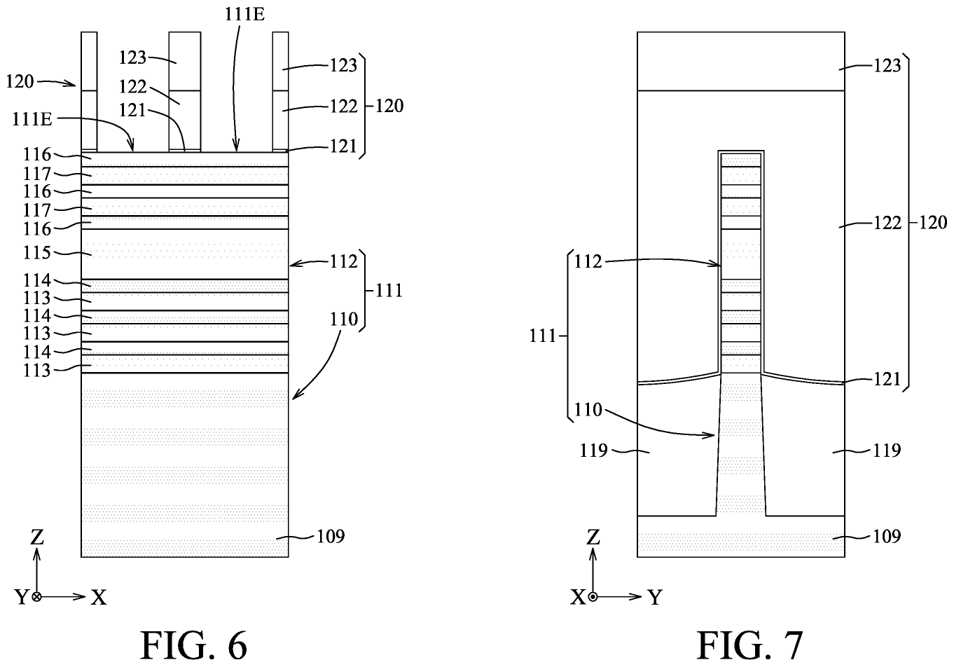

Referring to FIG. 1A and the examples illustrated in FIGS. 5 to 7, the method 1100 proceeds to step 1102, where a plurality of dummy gate portions 120 are formed over the fin structure 111 such that the fin structure 111 has a plurality of exposed regions 111E expose from the dummy gate portions 120 which are displaced from each other in an X direction transverse to the Z direction. FIG. 5 is a top schematic view illustrating the dummy gate portions 120 and the fin structure 111 in accordance with some embodiments, while other elements are omitted for purposes of simplicity and clarity. FIG. 6 is a schematic sectional view taken along line A-A′ of FIG. 5 in accordance with some embodiments. FIG. 7 is a schematic sectional view taken along line B-B′ of FIG. 5 in accordance with some embodiments, and is a view similar to that of FIG. 4, but illustrating the structure after step 1102. The number of the dummy gate portions 120 is determined according to application requirements. In FIGS. 5 and 6, three dummy gate portions 120 are shown in accordance to some embodiments. Each of the exposed regions 111E of the fin structure 111 includes a region of the upper fin portion 112 and a region of the upper part of the lower fin portion 110.

In some embodiments, each of the dummy gate portions 120 may include a dummy gate dielectric 121 formed on the fin structure 111, a dummy gate electrode 122 formed on the dummy gate dielectric 121 opposite to the fin structure 111, and a hard mask 123 formed on the dummy gate electrode 122 opposite to the dummy gate dielectric 121. In some embodiments, the hard mask 123 may include silicon nitride, silicon oxide, silicon oxynitride, or combinations thereof, the dummy gate electrode 122 may include polycrystalline silicon, single crystalline silicon, amorphous silicon, or combinations thereof, and the dummy gate dielectric 121 may include silicon oxide, silicon nitride, silicon oxynitride, high dielectric constant (k) materials, or combinations thereof. Other suitable materials for the dummy gate portion 120 are within the contemplated scope of the present disclosure.

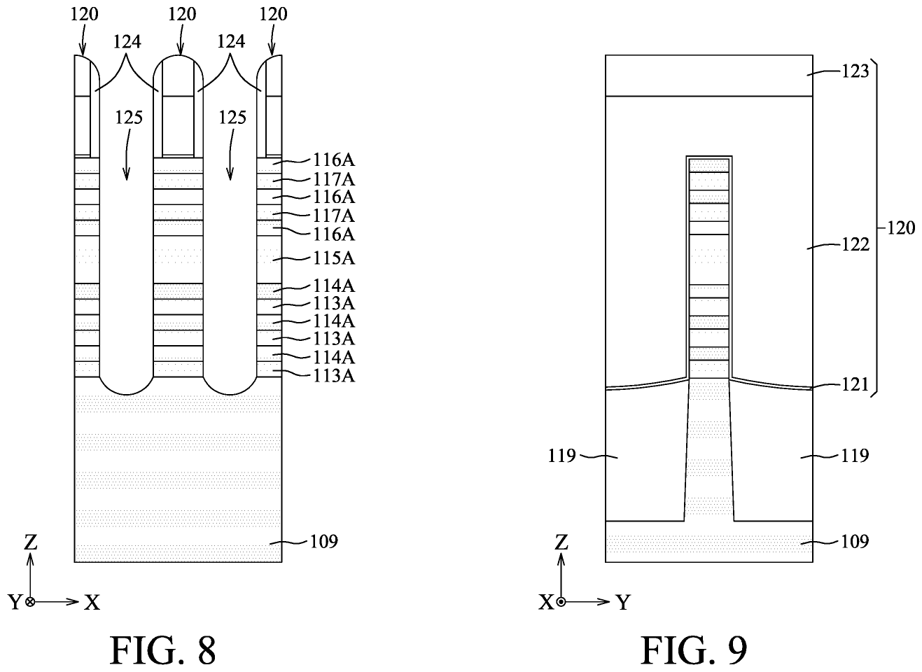

Referring to FIG. 1A and the examples illustrated in FIGS. 8 and 9, the method 1100 proceeds to step 1103, where two gate spacers 124 are respectively formed at two opposite sides of each of the dummy gate portions 120 in the X direction, and the exposed regions 111E (see FIG. 6) of the fin structure 111 are etched away to form source/drain recesses 125, respectively. FIGS. 8 and 9 are views similar to those of FIGS. 6 and 7, respectively, but illustrating the structures after step 1103.

In some embodiments, the gate spacers 124 may be formed by conformally depositing a dielectric material (not shown) for forming the gate spacers 124 over the structure shown in FIGS. 6 and 7 using, for example, CVD, ALD, or other suitable deposition techniques, followed by an anisotropic dry etching process until portions of the dielectric material, which are respectively formed on upper surfaces of the exposed regions 111E (see FIG. 6) and an upper surface of each of the dummy gate portions 120, are removed such that the two gate spacers 124 are selectively formed at the two opposite sides of each of the dummy gate portions 120.

In some embodiments, the dielectric material for forming the gate spacers 124 may include a nitride-based material, such as silicon nitride, silicon oxynitride, silicon carbon nitride, silicon oxycarbonitride, but is not limited thereto. Other materials suitable for forming the gate spacers 124 are within the contemplated scope of the present disclosure.

In some embodiments, after formation of the gate spacers 124, the exposed regions 111E may be etched away by dry etching, wet etching, other suitable processes, or combinations thereof. After step 1103, the first and second semiconductor films 114, 116 (see FIG. 6) are respectively patterned into first and second channel features 114A, 116A, and the first, second and third sacrificial films 113, 115, 117 are respectively patterned into first, second and third sacrificial features 113A, 115A, 117A.

Referring to FIG. 1A and the examples illustrated in FIGS. 9 and 13, the method 1100 proceeds to step 1104, where a plurality of inner spacers 126 and a plurality of first source/drain features 127 are formed. FIG. 13 is a view similar to that of FIG. 8, but illustrating the structures after step 1104, and the structure shown in FIG. 9 is substantially not changed after step 1104.

In some embodiments, step 1104 may include sub-steps 1104A to 1104H.

In sub-step 1104A, two opposite ends of the first, second and third sacrificial features 113A, 115A, 117A (see FIG. 8) are recessed through the source/drain recesses 125 to form lateral recesses (not shown) by an isotropic etching process, such as wet etching, or other suitable etching techniques. The remaining first, second and third sacrificial features are denoted by numerals 113B, 115B, 117B in the followings.

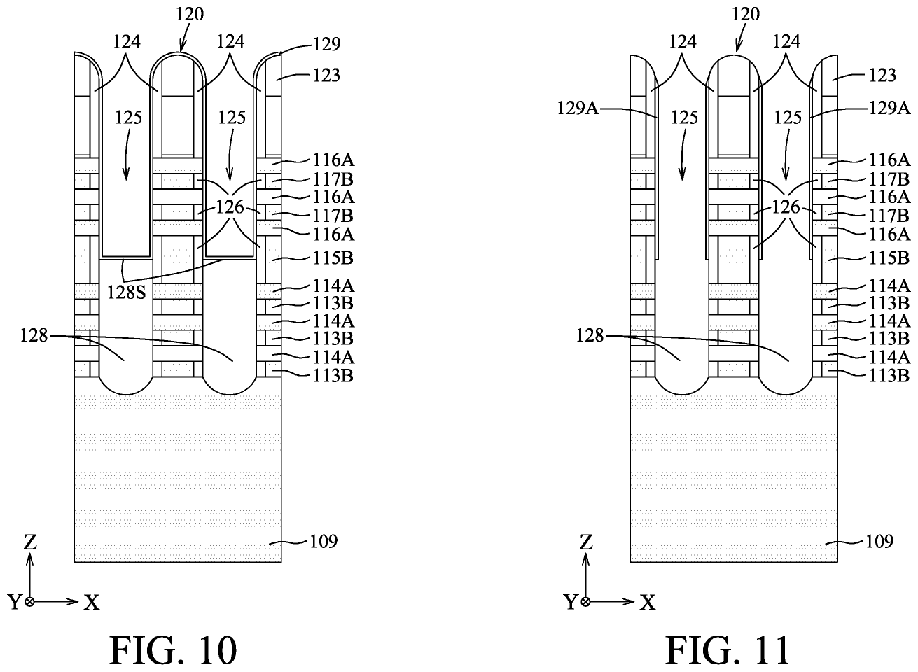

In sub-step 1104B, the inner spacers 126 are formed in the lateral recesses, respectively, to cover the remaining first, second and third sacrificial features 113B, 115B, 117B, as shown in FIG. 10. In some embodiments, sub-step 1104B includes: (i) depositing a spacer layer (not shown) on the structure obtained after sub-step 1104A to fill the lateral recesses by CVD, ALD, or other suitable deposition techniques, and (ii) removing excess portions of the spacer layer by an etching process, for example, but not limited to, a wet etching process, a dry etching process, other suitable etching techniques, or combinations thereof, so as to form the inner spacers 126 in the lateral recesses. In some embodiments, the spacer layer includes silicon oxide, silicon nitride, silicon oxynitride, other suitable dielectric materials, or combinations thereof. Other materials suitable for forming the spacer layer (i.e., materials for forming the inner spacers 126) are within the contemplated scope of the present disclosure.

Referring the example illustrated in FIG. 10, in sub-step 1104C, a plurality of dielectric portions 128 are respectively formed in the source/drain recesses 125 to cover the first channel features 114A. In some embodiments, each of the dielectric portions 128 has an upper surface 128S which has a height level higher than that of an upper surface of an uppermost one of the first channel features 114A and lower than that of a lower surface of a bottommost one of the second channel features 116A. In some embodiments, sub-step 1104C includes (i) depositing a filling material for forming the dielectric portions 128 to fill the source/drain recesses 125 (see FIG. 8) using CVD, ALD or other suitable processes, and (ii) etching back the filling material to form the dielectric portions 128 using, for example, but not limited to, dry etching, wet etching, other suitable processes, or combinations thereof. In some embodiments, the filling material is a material different from those of the hard mask 123 and the gate spacers 124, and includes silicon oxide, silicon oxycarbide, other suitable dielectric materials, or combinations thereof, so that the filling material may be selectively etched back while the hard mask 123 of each of the dummy gate portions 120 and the gate spacers 124 are less likely to be removed. Other materials suitable for forming the dielectric portions 128 are within the contemplated scope of the present disclosure.

Referring the example illustrated in FIG. 10, in sub-step 1104D, a blocking layer 129 is conformally deposited on the structure obtained after sub-step 1104C using CVD, ALD or other suitable processes. In some embodiments, the blocking layer 129 may be made of a material different from that of the dielectric portions 128, and includes silicon nitride, silicon carbon nitride, other suitable dielectric materials, or combinations thereof. Other materials suitable for forming the blocking layer 129 are within the contemplated scope of the present disclosure.

Referring the example illustrated in FIG. 11, in sub-step 1104E, an anisotropic etching process is performed to etch the blocking layer 129 until portions of the blocking layer 129 covering the dielectric portions 128 shown in FIG. 10 and upper surfaces of the dummy gate portions 120 and the gate spacers 124 are removed, so as to form a plurality of blocking films 129A covering end surfaces of the second channel features 116A and the inner spacers 126 aside the third sacrificial features 117B in the source/drain recesses 125. In some embodiments, the blocking films 129A also cover upper parts of the inner spacers 126 aside the second sacrificial features 115B.

Referring the example illustrated in FIG. 11, in sub-step 1104F, after forming the blocking films 129A, the dielectric portions 128 shown in FIG. 10 are removed using, for example, but not limited to, a dry etching process, a wet etching process, other suitable processes, or combinations thereof.

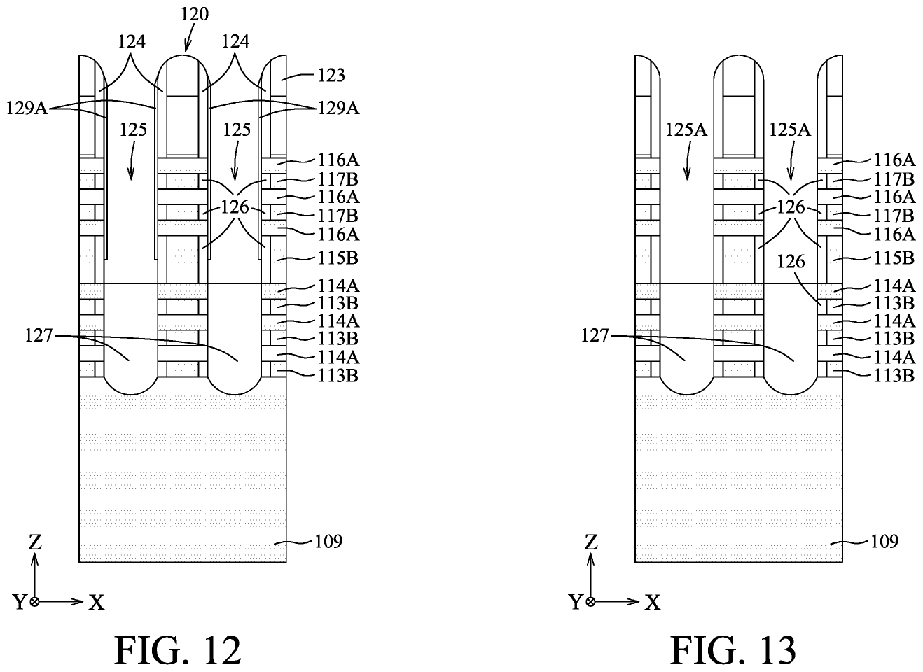

Referring the example illustrated in FIG. 12, in sub-step 1104G, the first source/drain features 127 are formed in lower portions of the source/drain recesses 125, respectively so as to cover end surfaces of the first channel features 114A in the source/drain recesses 125 shown in FIG. 11. After sub-step 1104G, each of the first channel features 114A is disposed to interconnect two adjacent ones of the first source/drain features 127. It is noted that after sub-step 1104F, the end surfaces of the first channel features 114A are exposed from the source/drain recesses 125 while the end surfaces of the second channel features 116A are blocked by the blocking films 129A, and thus the first source/drain features 127 can be prevented from being formed on the second channel features 116A.

The first source/drain features 127 may be doped with an n-type impurity or a p-type impurity, and may be formed as a single layer structure or a multi-layered structure having several sub-layers with different doping concentration. In some embodiments, each of the first source/drain features 127 may have a p-type conductivity, and includes single crystalline or polycrystalline silicon, single crystalline or polycrystalline silicon germanium, or other suitable materials doped with a p-type impurity so as to function as a source/drain of a p-FET. The p-type impurity may be, for example, but not limited to, boron (B), aluminum (Al), gallium (Ga), indium (In), other suitable materials, or combinations thereof. In some embodiments, each of the first source/drain features 127 may have an n-type conductivity, and includes single crystalline silicon, polycrystalline silicon or other suitable materials doped with an n-type impurity so as to function as a source/drain of an n-FET. The n-type impurity may be, for example, but not limited to, nitrogen (N), phosphorous (P), arsenic (As), antimony (Sb), other suitable materials, or combinations thereof. In some embodiments, carbon (C) may be selected to be doped in the first source/drain features 127. It is noted that each of the first source/drain features 127 may refer to a source or a drain, individually or collectively dependent upon the context.

Referring the example illustrated in FIG. 13, in sub-step 1104H, the blocking films 129A shown in FIG. 12 are removed using, for example, but not limited to, dry etching, wet etching, other suitable processes, or combinations thereof. Other suitable processes for forming the first source/drain features 127 in the lower portions of the source/drain recesses 125 (see FIG. 8) are within the contemplated scope of the present disclosure. After sub-step 1104H, the remaining source/drain recesses 125 are denoted by numeral 125A.

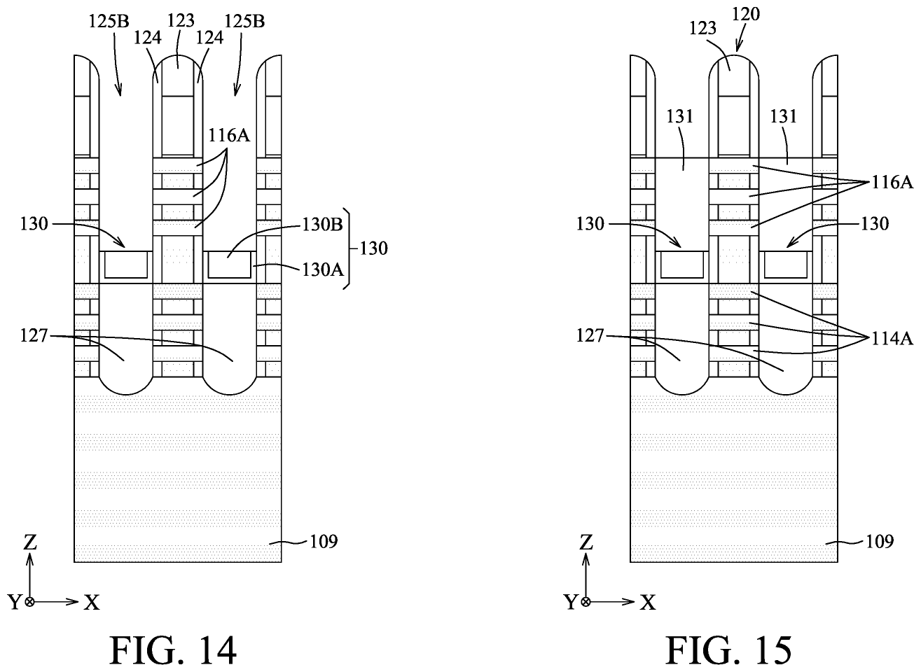

Referring to FIG. 1A and the examples illustrated in FIGS. 9 and 14, the method 1100 proceeds to step 1105, where a plurality of first isolation features 130 are formed respectively on the first source/drain features 127. FIG. 14 is a view similar to that of FIG. 13 in accordance with some embodiments, but illustrating the structure after step 1105, and the structure shown in FIG. 9 is substantially not changed after step 1105.

In some embodiments, each of the first isolation features 130 includes a first dielectric layer 130A and a second dielectric layer 130B, and may be formed by (i) conformally depositing a first material for forming the first dielectric layer 130A over the structure shown in FIG. 13 using CVD, ALD or other suitable processes, (ii) depositing a second material for forming the second dielectric layer 130B using CVD, ALD or other suitable processes so as to fill the remaining source/drain recesses 125A shown in FIG. 13, and (iii) etching back the first and second materials using, for example, but not limited to, dry etching, wet etching, other suitable processes, or combinations thereof, so as to form the first isolation features 130. In some embodiments, the first and the second materials may be the same or different from each other, and are different from those for the hard mask 123 and the gate spacers 124, so that the first and second materials may be selectively etched back while the hard mask 123 of each of the dummy gate portions 120 and the gate spacers 124 are less likely to be removed. Each of the first and second materials independently includes silicon oxide, silicon nitride, silicon oxynitride, other suitable dielectric materials, or combinations thereof. Other materials suitable for the first isolation features 130 are within the contemplated scope of the present disclosure.

After step 1105, the remaining source/drain recesses 125A (see FIG. 13) are denoted by numeral 125B, and the end surfaces of the second channel features 116A are exposed from the source/drain recesses 125B.

Referring to FIG. 1A and the examples illustrated in FIGS. 9 and 15, the method 1100 proceeds to step 1106, where a plurality of second source/drain features 131 are respectively formed on the first isolation features 130 so as to cover the end surfaces of the second channel features 116A in the source/drain recesses 125B shown in FIG. 14. FIG. 15 is a view similar to that of FIG. 14 in accordance with some embodiments, but illustrating the structure after step 1106, and the structure shown in FIG. 9 is substantially not changed after step 1106. After step 1106, each of the second channel features 116A is disposed to interconnect two adjacent ones of the second source/drain features 131.

Since suitable materials for the second source/drain features 131 are similar to those for the first source/drain features 127, details of possible materials for the second source/drain features 131 are omitted for the sake of brevity. It is noted that each of the second source/drain features 131 may refer to a source or a drain, individually or collectively dependent upon the context. In some embodiments, the first and second source/drain features 127, 131 may have the same type of conductivity, while in other embodiments, the first and second source/drain features 127, 131 may have different types of conductivity. When the first and second source/drain features 127, 131 have different types of conductivity, the semiconductor structure 500 may be used as an inverter.

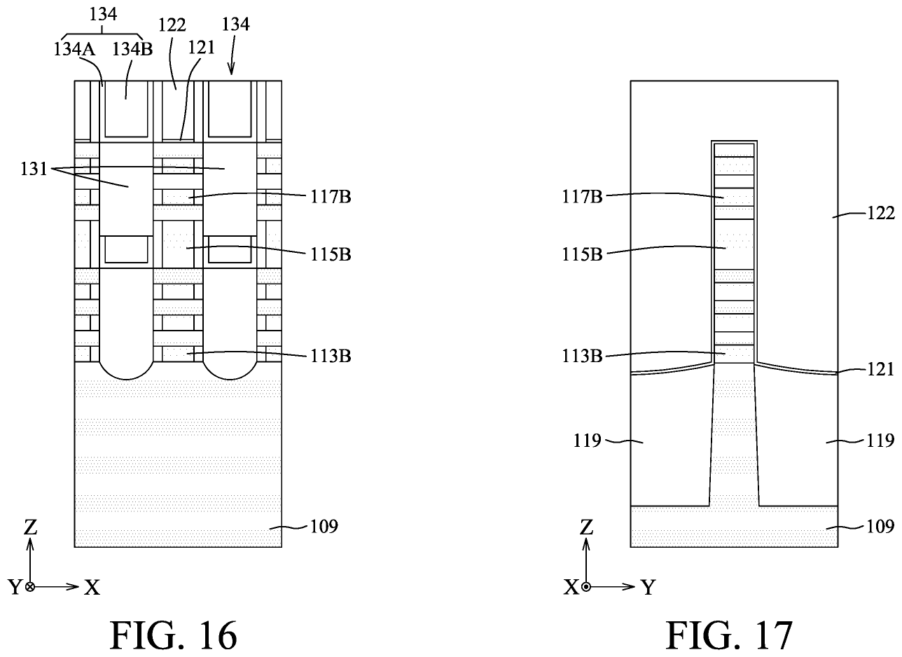

Referring to FIG. 1A and the examples illustrated in FIGS. 16 and 17, the method 1100 proceeds to step 1107, where a plurality of second isolation features 134 are respectively formed on the second source/drain features 131. FIGS. 16 and 17 are views similar to those of FIGS. 15 and 9, respectively, in accordance with some embodiments, but illustrating the structures after step 1107. In some embodiments, each of the second isolation features 134 includes a contact etching stop portion 134A and an inter-layer dielectric (ILD) portion 134B.

In some embodiments, step 1107 is performed by sequentially depositing a third material for forming the contact etching stop portion 134A and a fourth material for forming the ILD portion 134B over the structure shown in FIGS. 9 and 15 using a blanket deposition process, such as, but not limited to, CVD or molecular layer deposition (MLD), followed by a planarization process, for example, but not limited to, CMP, thereby removing the hard mask 123 of each of the dummy gate portions 120 shown in FIGS. 9 and 15 and exposing the dummy gate electrode 122. In some embodiments, the third and the fourth materials may be the same with or different from each other. Since the third and fourth materials are similar to the first and second materials as describe above with reference to FIG. 14, details of possible materials for each of the third and fourth materials are omitted for the sake of brevity. Other suitable materials and/or processes for the second isolation features 134 are within the contemplated scope of the present disclosure.

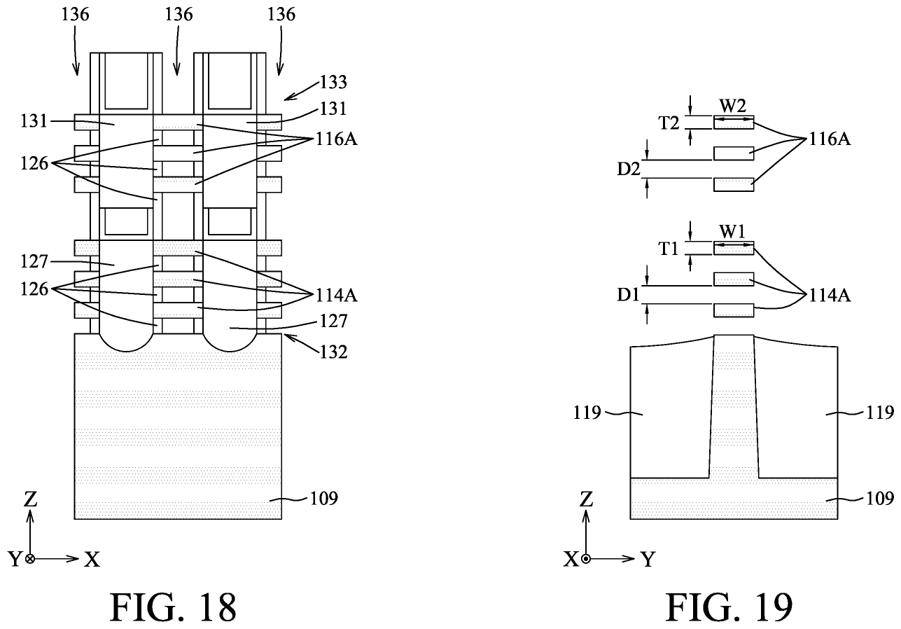

Referring to FIG. 1A and the examples illustrated in FIGS. 18 and 19, the method 1100 proceeds to step 1108, where the dummy gate electrode 122, the dummy gate dielectric 121, and the first, second and third sacrificial features 113B, 115B, 117B (see FIGS. 16 and 17) are removed to form a plurality of cavities 136 using dry etching, wet etching, other suitable processes, or combinations thereof. FIGS. 18 and 19 are views similar to those of FIGS. 16 and 17, respectively, in accordance with some embodiments, but illustrating the structures after step 1108.

In the following, the first and second channel features 114A, 116A refer to those exposed from a middle one of the cavities 136 as shown in FIG. 18, and do not refer to those exposed from a left one or a right one of the cavities 136. In some embodiments, after step 1108, a first semiconductor unit 132 and a second semiconductor unit 133 which are respectively disposed proximate to and distal from the semiconductor substrate 109 are formed. As shown in FIG. 18, the first semiconductor unit 132 includes the first source/drain features 127, the first channel features 114A extending between the first source/drain features 127, and the inner spacers 126 located at two opposite sides of each of the first source/drain features 127; and the second semiconductor unit 133 includes the second source/drain features 131, the second channel features 116A extending between the second source/drain features 131, and the inner spacers 126 located at two opposite sides of the second source/drain features 131.

Referring to FIG. 19, in some embodiments, two adjacent ones of the first channel features 114A are separated from each other in the Z direction by a distance (D1) ranging from about 8 nm to about 12 nm. In some embodiments, two adjacent ones of the second channel features 116A are separated from each other by a distance (D2) ranging from about 8 nm to about 12 nm. In some embodiments, each of the first and second channel features 114A, 116A may have a thickness (T1, T2) in the Z direction, and the thickness (T1, T2) ranges from about 4 nm to about 8 nm. In some embodiments, each of the first and second channel features 114A, 116A may have a width (W1, W2) in a Y direction transverse to both the X and Z directions, and each of the width (W1, W2) ranges from about 10 nm to about 80 nm. In some embodiments, the X, Y, and Z directions are perpendicular to one another.

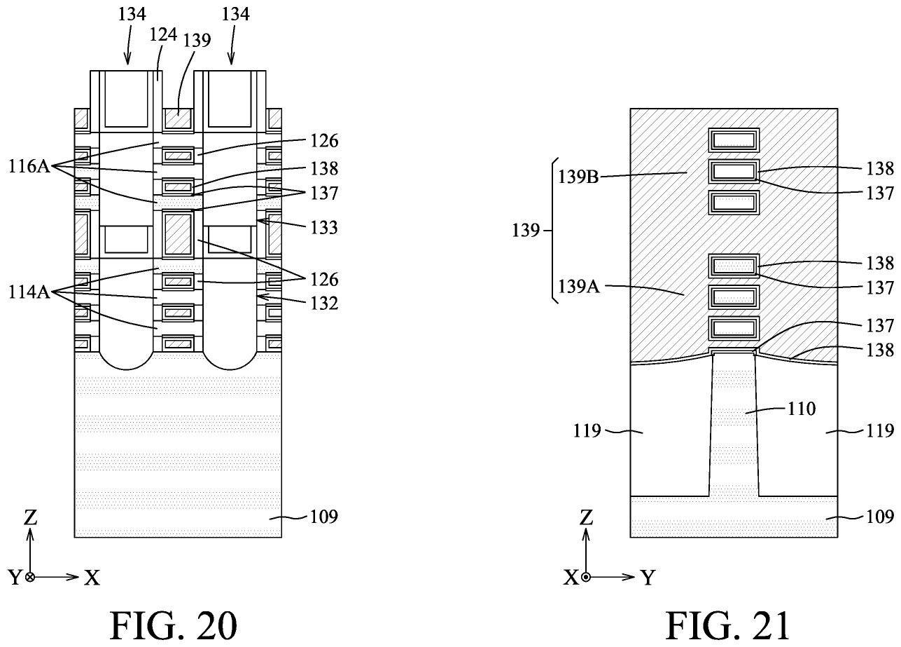

Referring to FIG. 1A and the examples illustrated in FIGS. 20 and 21, the method 1100 proceeds to step 1109 where a gate dielectric layer 138 and a gate material layer 139 are formed. FIGS. 20 and 21 are views similar to those of FIGS. 18 and 19, respectively, in accordance with some embodiments, but illustrating the structures after step 1109.

The gate dielectric layer 138 is disposed to surround the first and second channel features 114A, 116A. In some embodiments, the gate dielectric layer 138 may also be disposed on the inner spacers 126, the gate spacers 124, and the isolation regions 119. In some embodiments, the gate dielectric layer 138 includes silicon oxide, silicon nitride, silicon oxynitride, high dielectric constant (k) materials, other suitable materials, or combinations thereof. For example, the gate dielectric layer 138 may be made of hafnium oxide (HfOₓ), zirconium oxide (ZrO x), hafnium silicon oxide (HfSiOₓ), but is not limited thereto. Other suitable materials for the gate dielectric layer 138 are within the contemplated scope of the present disclosure.

The gate material layer 139 is disposed on the gate dielectric layer 138 such that the gate material layer 139 surrounds and is separated from the first and second channel features 114A, 116A of the first and second semiconductor units 132, 133 through the gate dielectric layer 138. In some embodiments, the gate material layer 139 has a proximate portion 139A and a distal portion 139B which are respectively proximate to and distal from the semiconductor substrate 109.

In some embodiments, the gate material layer 139 may be configured as a multi-layered structure including at least one work function metal which is provided for adjusting threshold voltage of the semiconductor devices 300, 400 (see FIG. 45), an electrically conductive material having a low resistance which is provided for reducing electrical conductivity of the gate material layer 139, other suitable materials, or combinations thereof. In some embodiments, the gate material layer 139 includes tungsten (W), titanium nitride (TiN), titanium (Ti), tantalum nitride (TaN), tantalum (Ta), aluminum (Al), ruthenium (Ru), or combinations thereof. Other suitable materials for the gate material layer 139 are within the contemplated scope of the present disclosure.

In some embodiments, as shown in FIGS. 20 and 21, a plurality of interfacial layers 137 are formed in step 1109, and the gate dielectric layer 138 is separated from each of the first and second channel features 114A, 116A through a corresponding one of the interfacial layers 137. The interfacial layers 137 are disposed to cover the first and second channel features 114A, 116A and disposed on upper and side surfaces of the lower fin portion 110. The interfacial layers 137 may serve as a buffer layer for facilitating growth of a layer to be subsequently formed thereon, and may include an insulating material. The insulating material includes silicon oxide, silicon nitride, silicon oxynitride, hafnium silicon oxide, or combinations thereof. Other suitable materials for the interfacial layers 137 are within the contemplated scope of the present disclosure.

In some embodiments, step 1109 may include (i) forming the interfacial layers 137 to cover the first and second channel features 114A, 116A using CVD, ALD, thermal oxidation, wet chemical oxidation, or other suitable techniques, (ii) depositing a dielectric material for forming the gate dielectric layer 138 using a blanket deposition process, such as, but not limited to, CVD, ALD, or other suitable deposition techniques, (iii) depositing materials for forming the gate material layer 139 using CVD, ALD or other suitable processes to fill the cavities 136 (see FIG. 18), and (iv) performing a planarization process, for example, but not limited to, CMP, or other suitable processes, to expose the second isolation features 134, followed by an etching back process, for example, but not limited to, dry etching, wet etching, other suitable processes, or combinations thereof, thereby obtaining the gate dielectric layer 138 and the gate material layer 139.

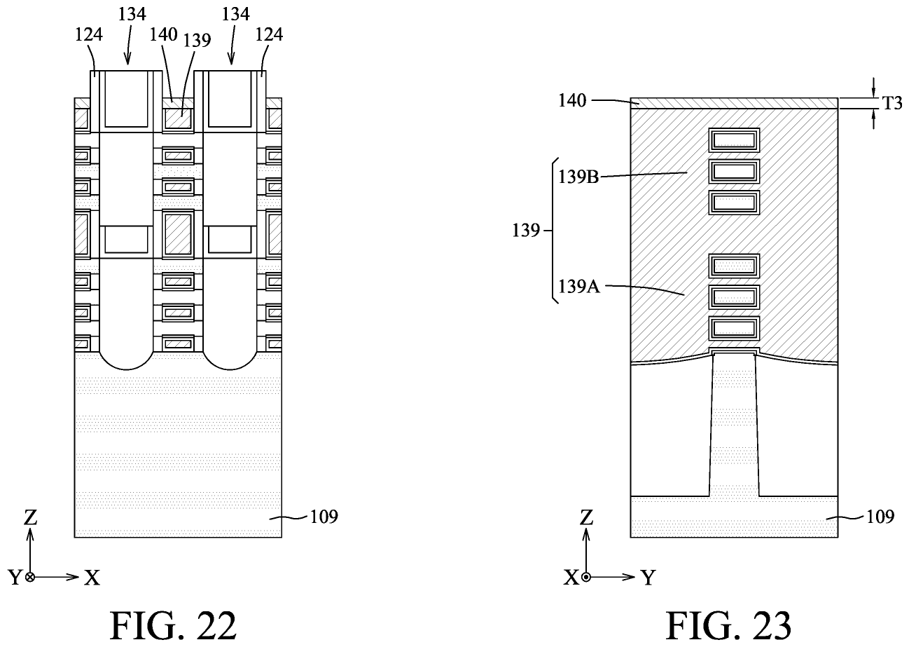

Referring to FIG. 1A and the examples illustrated in FIGS. 22 and 23, the method 1100 proceeds to step 1110, where an electrically conductive capping layer 140 is formed on the distal portion 139B of the gate material layer 139. FIGS. 22 and 23 are views similar to those of FIGS. 20 and 21, respectively, in accordance with some embodiments, but illustrating the structures after step 1110.

In some embodiments, as shown in FIG. 22, the electrically conductive capping layer 140 is selectively formed on the gate material layer 139, and is less likely to be formed on the dielectric materials (i.e., the gate spacers 124 and the second isolation features 134) by CVD, ALD, or other suitable deposition techniques. In some embodiments, the electrically conductive capping layer 140 may include W, TiN, TaN, Ta, Al, Ru, or combinations thereof. Other suitable materials for the electrically conductive capping layer 140 are within the contemplated scope of the present disclosure. In some embodiments, the electrically conductive capping layer 140 has a thickness (T3) ranging from about 2 nm to about 15 nm. If the thickness (T3) is too small (for example, less than about 2 nm), the electrical conductivity for an electrically conductive capping feature 140A obtained by pattering the electrically conductive capping layer 140 may be insufficient. If the thickness (T3) is too large (for example, greater than about 15 nm), a fringing capacitance may be unduly increased.

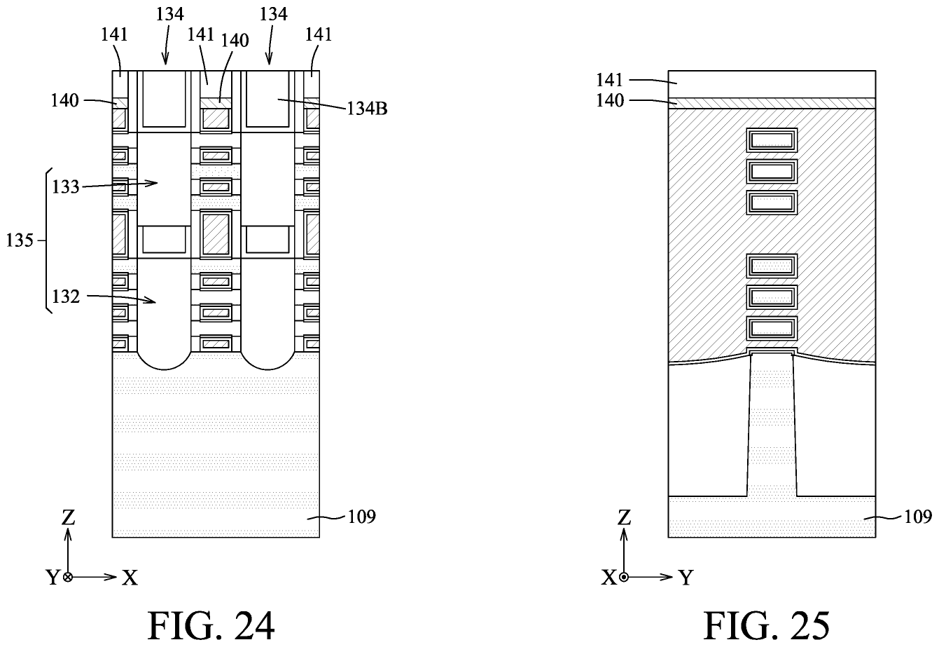

Referring to FIG. 1A and the examples illustrated in FIGS. 24 and 25, the method 1100 proceeds to step 1111, where a self-aligned dielectric layer 141 is formed on the electrically conductive capping layer 140. FIGS. 24 and 25 are views similar to those of FIGS. 22 and 23, respectively, in accordance with some embodiments, but illustrating the structures after step 1111.

In some embodiments, step 1111 may include (i) depositing a fifth dielectric material for forming the self-aligned dielectric layer 141 on structure shown in FIGS. 22 and 23 using a blanket deposition process, such as, but not limited to, CVD, ALD, or other suitable deposition techniques, and (ii) performing a planarization process, for example, but not limited to, CMP, or other suitable processes, to expose the second isolation features 134, thereby obtaining the self-aligned dielectric layer 141.

In some embodiments, the self-aligned dielectric layer 141 includes a material the same as or different from those of the gate spacers 124 and the second isolation features 134, and may include silicon nitride (e.g., SiN), aluminum oxide (e.g., Al₂O₃), hafnium oxide (e.g., HfO₂), zirconium oxide (e.g., ZrO₂), silicon carbide (e.g., SiC), or combinations thereof.

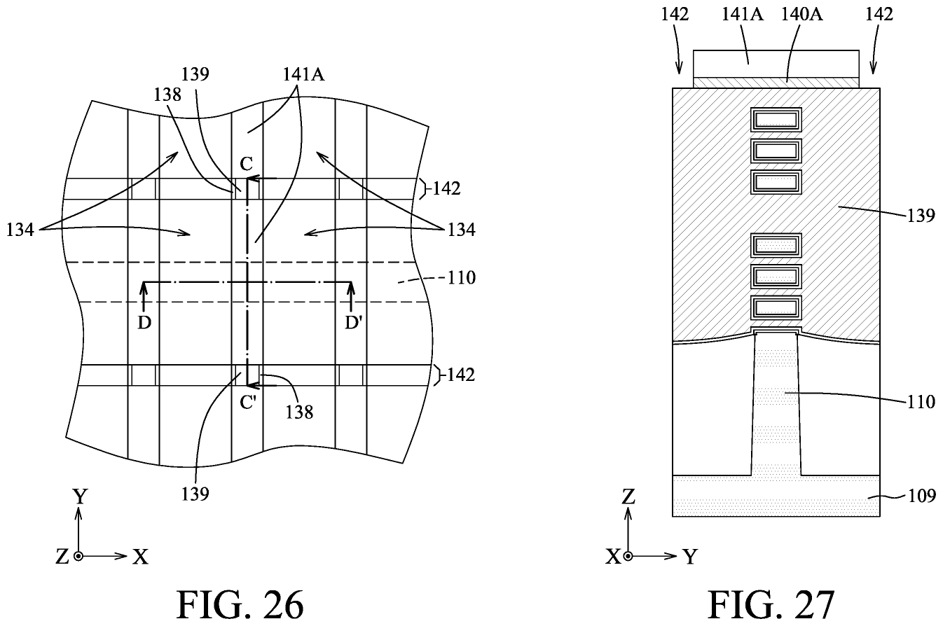

Referring to FIG. 1B and the examples illustrated in FIGS. 24, 26 and 27, the method 1100 proceeds to step 1112, where the electrically conductive capping layer 140 and the self-aligned dielectric layer 141 (see FIG. 25) are patterned into the electrically conductive capping feature 140A and a self-aligned dielectric feature 141A. After step 1112, two first cutout portions 142, which are spaced apart from each other in the Y direction, are formed at two opposite sides of a stack 135 of the first and second semiconductor units 132, 133 (see also FIG. 24). FIG. 26 is a top view illustrating the first cutout portions 142 and the gate material layer 139 exposed from the cutout portions 142 in accordance with some embodiments. FIG. 27 is a schematic sectional view taken along line C-C′ of FIG. 26 in accordance with some embodiments and is a view similar to that of FIG. 25, but illustrating the structure after step 1112. A schematic sectional view taken along line D-D′ of FIG. 26 in accordance with some embodiments is substantially the same as the schematic sectional view shown in FIG. 24.

In some embodiments, as shown in FIG. 26, each of the first cutout portions 142 extends oppositely in the X direction into the second isolation features 134 which are formed at two opposite sides of the gate material layer 139.

In some embodiments, step 1112 may include (i) forming a photoresist on the structure obtained after step 1111, (ii) performing a lithography process to form a patterned photoresist, and (iii) performing an etching process to etch the electrically conductive capping layer 140, the self-aligned dielectric layer 141 (see FIG. 25) and the second isolation features 134 through the patterned photoresist using, for example, dry etching, wet etching, other suitable etching techniques, or combinations thereof, thereby obtaining the first cutout portions 142. In some embodiments, the etching process may be a time-controlled etching process so that the etching is stopped after a period of time, thereby preventing the gate material layer 139 formed beneath the electrically conductive capping layer 140 from being over-etched.

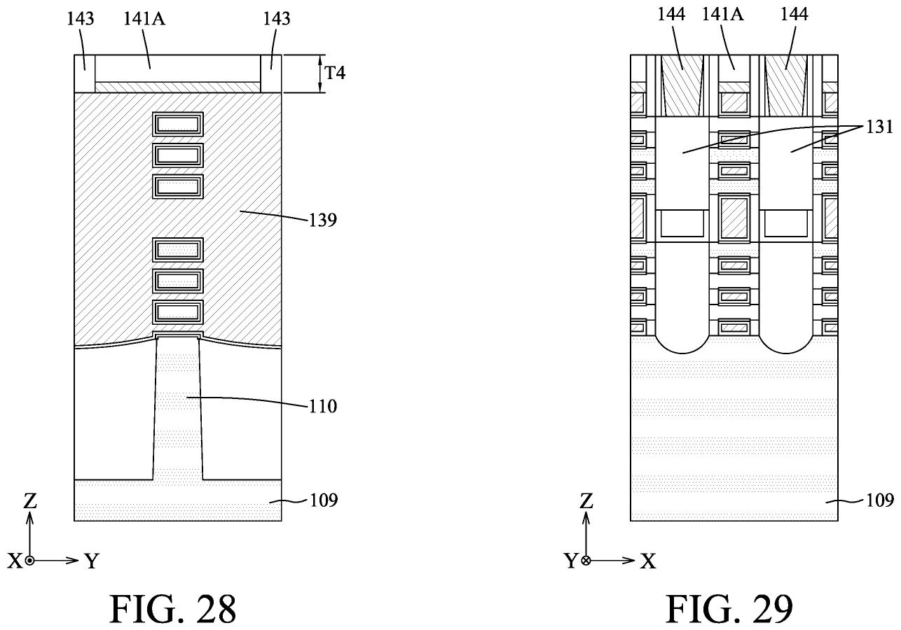

Referring to FIG. 1B and the examples illustrated in FIGS. 24 and 28, the method 1100 proceeds to step 1113, where two first fillers 143 are respectively formed in the two first cutout portions 142 shown in FIG. 27. FIG. 28 is a view similar to that of FIG. 27 in accordance with some embodiments, but illustrating the structures after step 1113, and the structure shown in FIG. 24 is substantially not changed after step 1113.

In some embodiments, the first fillers 143 include silicon oxide, silicon nitride, silicon oxynitride, silicon carbon nitride, silicon oxycarbonitride, silicon oxycarbide, silicon carbide, aluminum oxide, hafnium oxide, zirconium oxide, or combinations thereof. Other suitable materials for the first fillers 143 are within the contemplated scope of the present disclosure. In some embodiments, each of the first fillers 143 may have a thickness (T4) ranging from about 5 nm to about 30 nm.

In some embodiments, step 1113 may include filling a dielectric material for forming the first fillers 143 in the first cutout portions 142 using for example, but not limited to, ALD, CVD, or other suitable techniques, and removing an excess of the dielectric material for forming the first fillers 143 to expose the self-aligned dielectric feature 141A using CMP, or other suitable techniques, thereby obtaining the first fillers 143.

Referring to FIG. 1B and the examples illustrated in FIGS. 28 and 29, the method 1100 proceeds to step 1114, where a plurality of first contact features 144 are formed in the second isolation features 134 shown in FIG. 24. FIG. 29 is view similar to that of FIG. 24 in accordance with some embodiments, but illustrating the structure after step 1114, and the structure shown in FIG. 28 is substantially not changed after step 1114.

In some embodiments, step 1114 may include (i) forming a patterned mask layer (not shown) on the structure obtained after step 1113 using a lithography process, (ii) performing an etching process (for example, but not limited to, dry etching, wet etching, or a combination thereof) through the patterned mask layer to form openings (not shown), each extending through a corresponding one of the second isolation features 134 shown in FIG. 24 to expose a corresponding one of the second source/drain features 131, (iii) filling a conductive material for forming the first contact features 144 in the openings using for example, but not limited to, ALD, CVD, plating, or other suitable techniques, and (iv) removing an excess of the conductive material for forming the first contact features 144 to expose the self-aligned dielectric feature 141A using CMP or other suitable techniques to form the first contact features 144. In some embodiments, the conductive material for forming the first contact features 144 may include, for example, but not limited to, copper, tungsten, cobalt, ruthenium, aluminum, palladium, nickel, platinum, a low resistivity metal constituent, or the like, or combinations thereof. Other suitable materials and/or processes for forming the first contact features 144 are within the contemplated scope of the present disclosure.

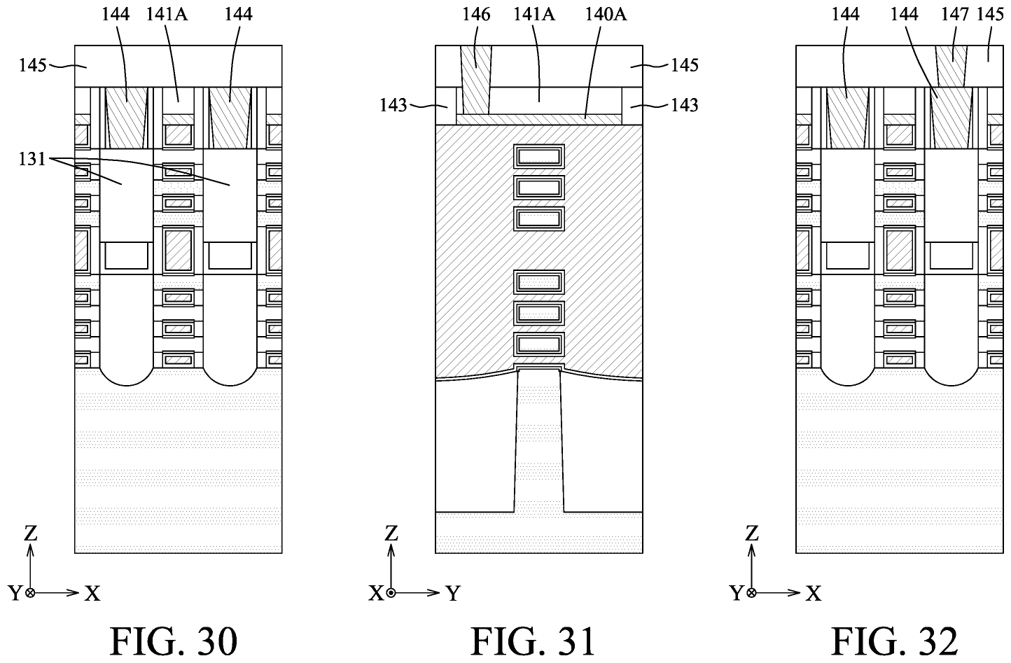

Referring to FIG. 1B and the examples illustrated in FIGS. 30 and 31, the method 1100 proceeds to step 1115 where a gate via 146 is formed. FIGS. 30 and 31 are views similar to those of FIGS. 29 and 28, respectively, in accordance with some embodiments, but illustrating the structures after step 1115.

In some embodiments, step 1115 may include (i) forming a first ILD layer 145 on the structure shown in FIGS. 28 and 29 using a blanket deposition process, for example, but not limited to, CVD, MLD or other suitable techniques, (ii) forming a patterned mask (not shown) on the first ILD layer 145 using a lithography process, (iii) performing an etching process (for example, but not limited to, dry etching, wet etching, or a combination thereof) through the patterned mask to form a gate via opening (not shown) which extends through the first ILD layer 145 and the self-aligned dielectric feature 141A to expose the electrically conductive capping feature 140A, (iv) filling the gate via opening with a material for forming the gate via 146 using, for example, ALD, CVD, plating, or other suitable techniques, and (v) removing an excess of the material for forming the gate via 146 and removing the patterned mask to expose the first ILD layer 145, thereby obtaining the gate via 146.

Since suitable materials for the first ILD layer 145 and the gate via 146 may be respectively similar to those for the ILD portion 134B and the first contact features 144, details thereof are omitted for the sake of brevity. Other suitable materials and/or processes for forming the first ILD layer 145 and the gate via 146 are within the contemplated scope of the present disclosure.

Referring to FIG. 1B and the examples illustrated in FIGS. 31 and 32, the method 1100 proceeds to step 1116, where two contact vias 147 (one of which is shown in FIG. 32 and the other one of which is in the other not shown cross-section) are formed. FIG. 32 is a view similar to that of FIG. 30 in accordance with some embodiments, but illustrating the structure after step 1116, and the structure shown in FIG. 31 is substantially not changed after step 1116.

In some embodiments, step 1116 includes (i) forming a patterned mask (not shown) on the structure after step 1115, (ii) performing an etching process (for example, but not limited to, dry etching, wet etching, or a combination thereof) through the patterned mask to form two contact via openings (not shown) which extends through the first ILD layer 145 to respectively expose the first contact features 144, (iii) filling the contact via openings with a material for forming the contact vias 147 using, for example, ALD, CVD, plating, or other suitable techniques, and (iv) removing an excess of the material for forming the contact vias 147 and removing the patterned mask to expose the first ILD layer 145, thereby obtaining the contact vias 147. Since materials for forming the contact vias 147 are similar to those for the first contact features 144, details thereof are omitted for the sake of brevity. Other suitable materials and/or processes for forming the contact vias 147 are within the contemplated scope of the present disclosure.

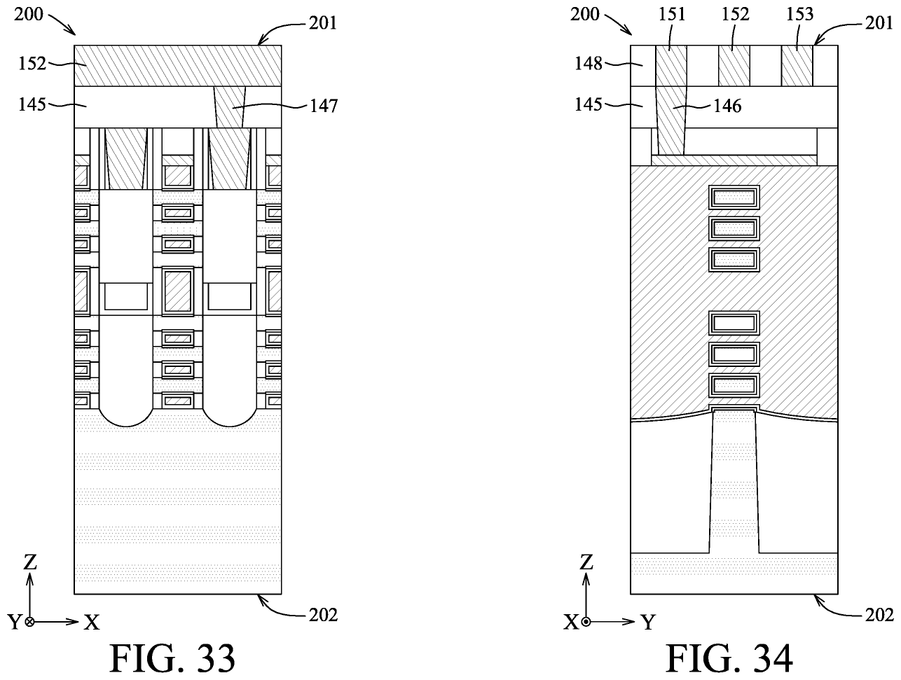

Referring to FIG. 1B and the examples illustrated in FIGS. 33 and 34, the method 1100 proceeds to step 1117, where first, second, and third metal lines 151, 152, 153 are formed in a second ILD layer 148 which is formed on the first ILD layer 145. The first metal line 151 is electrically connected to the gate via 146, and the second and third metal lines 152, 153 are respectively electrically connected to the contact vias 147. FIGS. 33 and 34 are views similar to those of FIGS. 32 and 31, respectively, in accordance with some embodiments, but illustrating the structures after step 1117.

In some embodiments, step 1117 includes (i) forming the second ILD layer 148 on the first ILD layer 145 in a manner similar to that for forming the first ILD layer 145, (ii) forming a patterned masking (not shown) on the second ILD layer 148 using a lithography process, (iii) performing an etching process (for example, but not limited to, dry etching, wet etching, or a combination thereof) through the patterned masking to form three grooves which extend through the second ILD layer 148 to respectively expose the gate via 146 and the contact vias 147, (iv) filling the three grooves with a material for forming the first, second, third metal lines 151, 152, 153 using, for example, ALD, CVD, plating, or other suitable techniques, and (v) removing an excess of the material for forming the first, second, third metal lines 151, 152, 153 and removing the patterned masking to expose the second ILD layer 148, thereby obtaining the first, second, third metal lines 151, 152, 153. Since materials for forming the first, second, third metal lines 151, 152, 153 are similar to those for the first contact features 144, details thereof are omitted for the sake of brevity. Other suitable processes for forming the first, second, third metal lines 151, 152, 153 are within the contemplated scope of the present disclosure.

After step 1117, a semi-product 200 is thus formed, as shown in FIGS. 33 and 34. The semi-product 200 has a front-side surface 201 opposite to the semiconductor substrate 109 and a backside surface 202 opposite to the front-side surface 201.

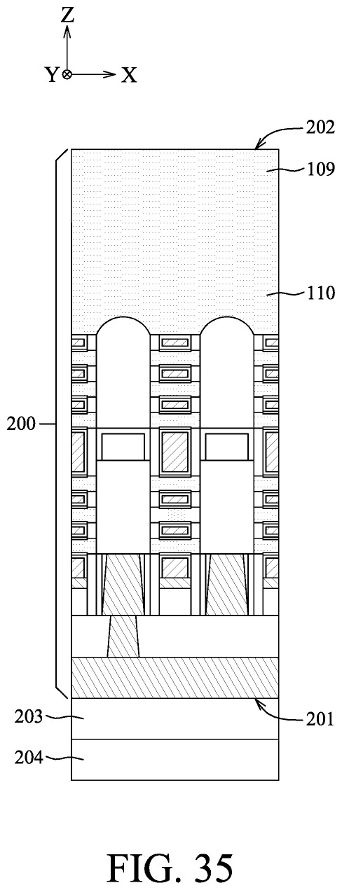

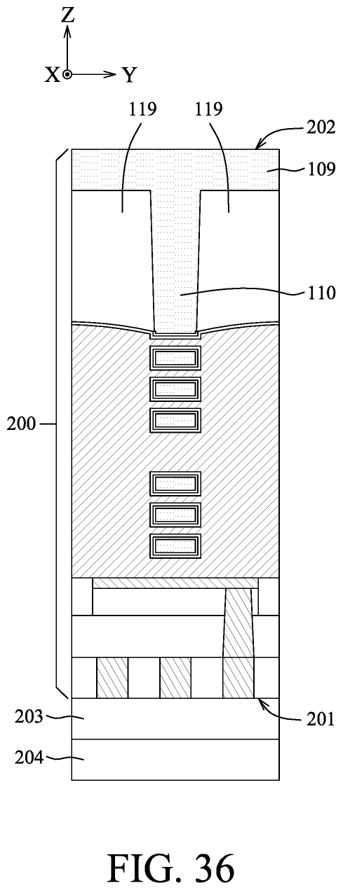

Referring to FIG. 1B and the examples illustrated in FIGS. 35 and 36, the method 1100 proceeds to step 1118, where the semi-product 200 is flipped upside down through a carrier substrate 204. FIGS. 35 and 36 are views similar to those of FIGS. 33 and 34, respectively, in accordance with some embodiments, but illustrating the structures after step 1118.

In some embodiments, step 1118 may include (i) forming a dielectric bonding layer 203 on the front-side surface 201 of the semi-product 200 by CVD, ALD, or other suitable deposition techniques, (ii) bonding the carrier substrate 204 to the front-side surface 201 of the semi-product 200 through the dielectric bonding layer 203, and (iii) flipping the semi-product 200 upside down through the carrier substrate 204. In some embodiments, the bond dielectric layer 203 may be a silicon dioxide layer. In some embodiments, the carrier substrate 204 may be made of a material that is similar to those for the semiconductor substrate 109, and thus details thereof are omitted for the sake of brevity. Other suitable materials for the bond dielectric layer 203 and the carrier substrate 204 are within the contemplated scope of the present disclosure.

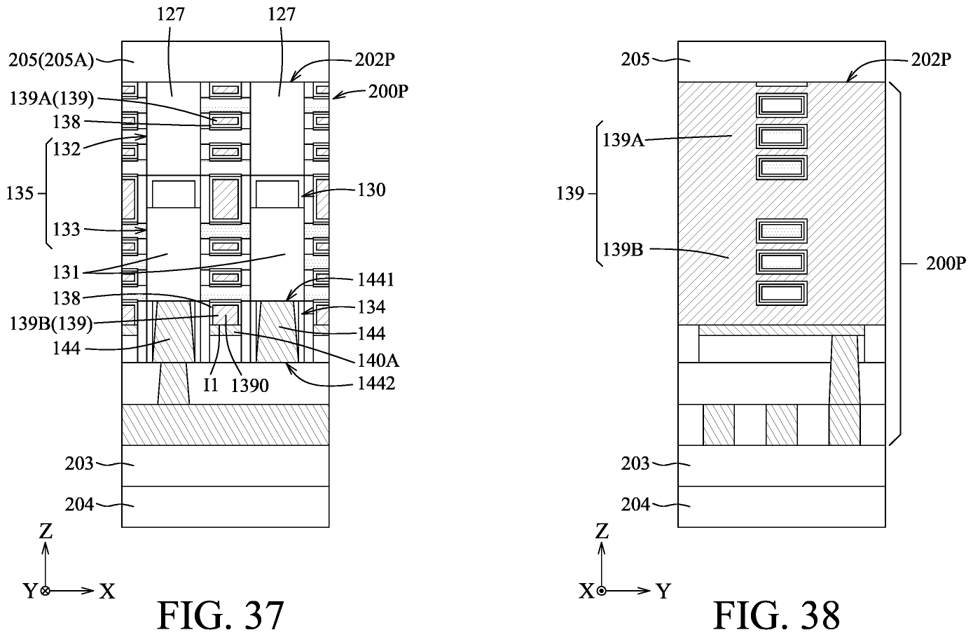

Referring to FIG. 1B and the examples illustrated in FIGS. 37 and 38, the method 1100 proceeds to step 1119, where a third ILD layer 205 is formed. FIGS. 37 and 38 are views similar to those of FIGS. 35 and 36, respectively, in accordance with some embodiments, but illustrating the structures after step 1119.

In some embodiments, step 1119 may include (i) removing the semiconductor substrate 109 (shown in FIGS. 35 and 36) from the backside surface 202 of the semi-product 200 using a planarization process (for example, but not limited to, CMP) and/or an etching process to expose the proximate portion 139A of the gate dielectric layer 139 and the first source/drain features 127, such that a backside-polished semi-product 200P having a backside surface 202P opposite to the carrier substrate 204 is formed, and such that the gate material layer 139 can be patterned from the proximate portion 139A during subsequent processes, and (ii) forming the third ILD layer 205 on the backside surface 202P of the backside-polished semi-product 200P by CVD, ALD, or other suitable deposition techniques. In some embodiments, the lower fin portion 110 and the isolation portions 119 are removed after step 1119.

In some embodiments, the third ILD layer 205 may be made of a material that is similar to those for forming the first ILD layer 145 as described above with reference to FIGS. 30 and 31, and thus details thereof are omitted for the sake of brevity.

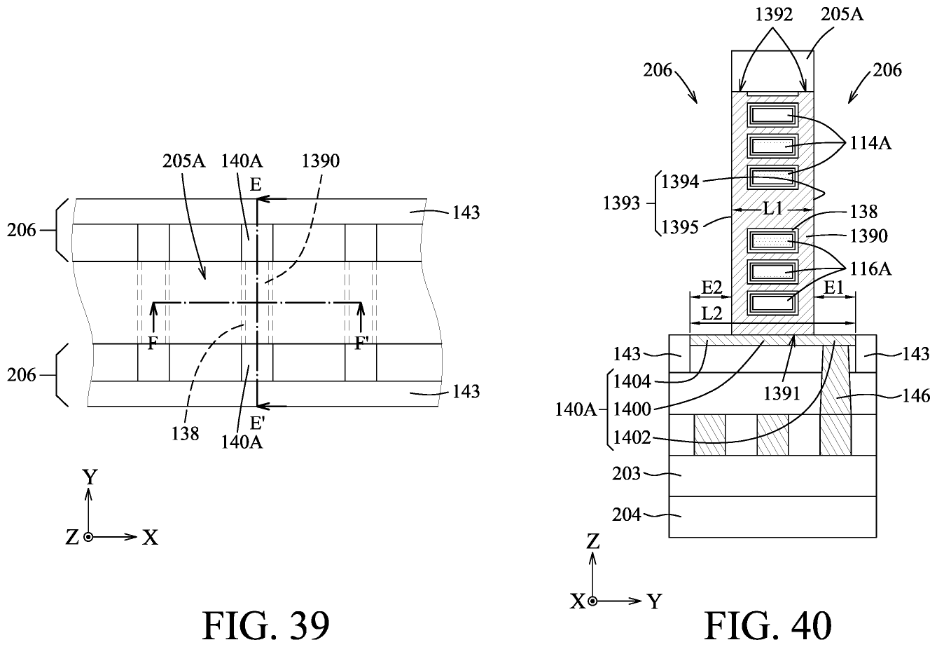

Referring to FIG. 1B and the examples illustrated in FIGS. 37, 39 and 40, the method 1100 proceeds to step 1120, where the third ILD layer 205 and the gate material layer 139 (see FIG. 38) are respectively patterned into an ILD feature 205A and a gate feature 1390. After step 1120, two second cutout portions 206, which are spaced apart from each other in the Y direction, are formed at two opposite sides of the stack 135 of the first and second semiconductor units 132, 133 (see also FIG. 37). FIG. 39 is a top schematic view illustrating the second cutout portions 206 and the electrically conductive capping feature 140A exposed from the second cutout portions 206 in accordance with some embodiments. In some embodiments, the first fillers 143 are also exposed from the second cutout portions 206, respectively. FIG. 40 is a schematic sectional view taken along line E-E′ of FIG. 39 in accordance with some embodiment, and is a view similar to that of FIG. 38, but illustrating the structure after step 1120. A schematic sectional view taken along line F-F′ of FIG. 39 in accordance with some embodiments is substantially the same as that shown in FIG. 37.

In some embodiments, as shown in FIG. 39, each of the second cutout portions 206 extends oppositely in the X direction into the first and second isolation features 130, 134 which are formed at two opposite sides of the gate material layer 139 in the X direction (see FIG. 37). It should be noted that each of the first isolation features 130 is formed to around a periphery of a corresponding one of the first source/drain features 127 and is elongated in the Y direction, and each of the second isolation features 134 is formed to around a periphery of a corresponding one of the second source/drain features 131 and is elongated in the Y direction. In some embodiments, after forming the ILD feature 205A, portions of the first and second isolation features 130, 134, portions of the gate material layer 139, and portions of the gate dielectric layer 138, which are exposed from the ILD feature 205A are removed until the electrically conductive capping feature 140A is exposed.

In some embodiments, step 1120 includes (i) forming a photoresist on the structure obtained after step 1119, and then performing a lithography process to form a patterned photoresist, and (ii) performing an etching process to etch the third ILD layer 205, the gate material layer 139, the gate dielectric layer 138 (see FIG. 38), and the first and second isolation features 130, 134 through the patterned photoresist using, for example, dry etching, wet etching, other suitable etching techniques, or combinations thereof, thereby obtaining the second cutout portions 206.

After step 1120, referring to FIGS. 38 and 40, the distal portion 139B of the gate material layer 139 is patterned to have a first surface 1391 of the gate feature 1390 and the proximate portion 139A of the gate material layer 139 is patterned to have a second surface 1392 of the gate feature 1390.

Referring to FIG. 40, the gate feature 1390 is disposed on the gate dielectric layer 138, and the gate feature 1390 is disposed to surround the first and second channel features 114A, 116A, and is separated from the first and second channel features 114A, 116A by the gate dielectric layer 138.

In addition, the gate feature 1390 further has an interconnect surface 1393 which interconnects the first and second surface 1391, 1392. The electrically conductive capping feature 140A is in direct contact with the first surface 1391, and extends beyond the interconnect surface 1393. In some embodiments, the gate feature 1390 has a first length (L1) in the Y direction, and the electrically conductive capping feature 140A has a second length (L2) in the Y direction which is greater than the first length (L1) of the gate feature 1390.

Referring to FIG. 37, it can be seen that the first and second semiconductor units 132, 133 are disposed to distal from and proximate to the electrically conductive capping feature 140A, respectively. Furthermore, each of the first contact features 144 has a contact surface 1441 in contact with a corresponding one of the second source/drain features 131 of the second semiconductor unit 133, and an opposite surface 1442 opposite to the contact surface 1441. An interface (I1) between the electrically conductive capping feature 140A and the gate feature 1390 is located coincident with a first reference surface which is located between the contact surface 1441 and the opposite surface 1442 of each of the first contact features 144.

In some embodiments, as shown in FIG. 40, the electrically conductive capping feature 140A includes a main portion 1400, a first extending portion 1402, and a second extending portion 1404. The main portion 1400 is in direct contact with the first surface 1391 of the gate feature 1390. The interconnect surface 1393 of the gate feature 1390 has a first end region 1394 and a second end region 1395 opposite to each other in the Y direction. In some embodiments, the first extending portion 1402 extends from the main portion 1400 beyond the first end region 1394 by a distance (E1), and the second extending portion 1404 extends from the main portion 1400 beyond the second end region 1395 by a distance (E2). In some embodiments, as shown in FIG. 40, the distance (E1) is equal to the distance (E2). In some embodiments, each of the distances (E1, E2) ranges from about 2 nm to about 20 nm.

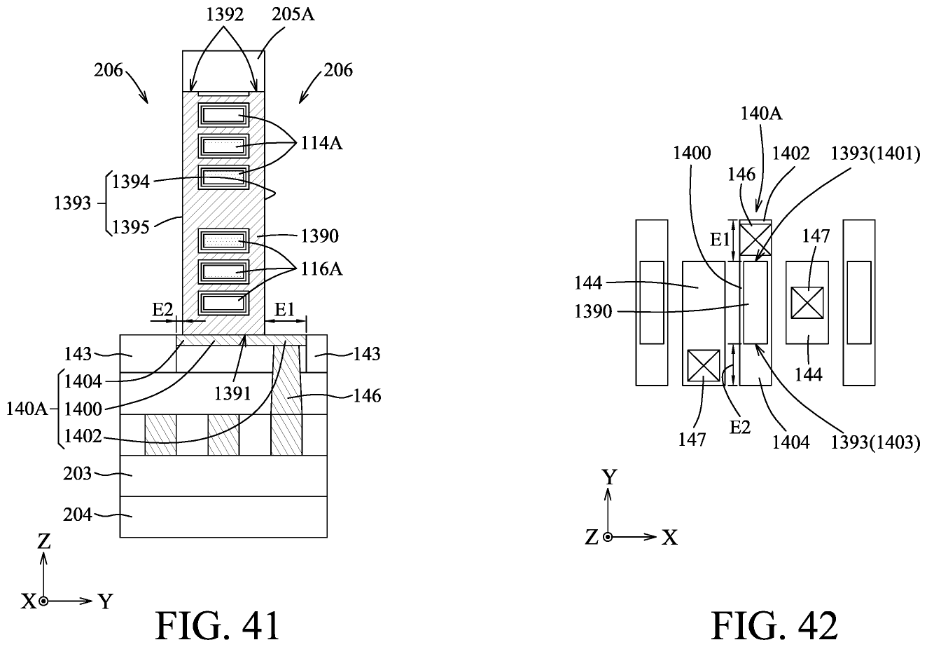

FIG. 41 is a view similar to that of FIG. 40, but illustrating a variant of the electrically conductive capping feature 140A in accordance to some embodiments, where the distance (E1) is greater than the distance (E2). In some embodiments, when the gate via 146 is configured to be disposed on the first extending portion 1402 of the electrically conductive capping feature 140A, the distance (E2) may range from about 0 nm to about 20 nm.

FIG. 42 is a schematic view illustrating relationships among the gate feature 1390, the electrically conductive capping feature 140A, the two first contact features 144, the two contact vias 147, and the gate via 146 in accordance with some embodiments, while other elements are omitted for purposes of simplicity and clarity.

Referring to FIG. 42, the main portion 1400 has a first end 1401 and a second end 1403 opposite to the first end 1401 in the Y direction. The first extending portion 1402 extends from the first end 1401 of the main portion 1400 beyond the interconnect surface 1393 of the gate feature 1390. The second extending portion 1404 extends from the second end 1403 of the main portion 1400 beyond the interconnect surface 1393 of the gate feature 1390. Each of the first and second extending portions 1402, 1404 extends beyond the interconnect surface 1393 by a distance (E1, E2) not greater than about 20 nm. At least one of the first and second extending portions 1402, 1404 extends beyond the interconnect surface 1393 by a distance (E1, E2) greater than about 2 nm.

In some embodiments, as shown in FIG. 42, the gate via 146 is in direct contact with the first extending portion 1402 of the electrically conductive capping feature 140A, and is staggered from the two contact vias 147 in both the X and Y directions.

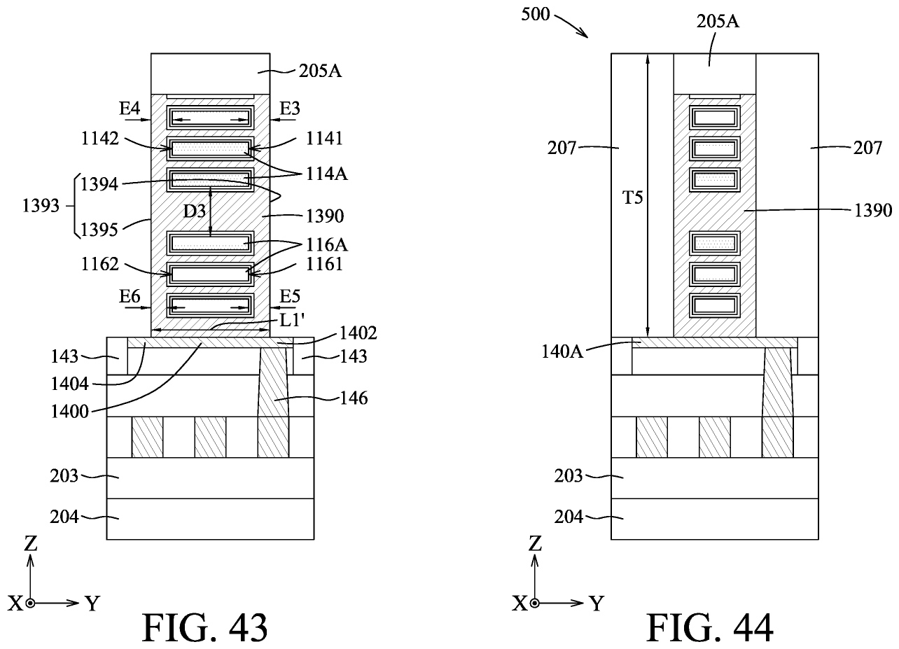

FIG. 43 is a view similar to that of FIG. 40, but illustrating a variant of the gate feature 1390 in accordance to some embodiments. The gate feature 1390 shown in FIG. 43 has a first length (L1′) in the Y direction greater than that (L1) of the gate feature 1390 shown in FIG. 40, because each of the first and second channel features 114A, 116A has a relatively greater width in the Y direction. In this case, a projection of the gate feature 1390 on an X-Y plane (for example, the carrier substrate 204) may partially overlap a projection of the gate via 146 on the X-Y plane. In some other embodiments, as shown in FIG. 40, the projection of the gate feature 1390 on the X-Y plane may not overlap the projection of the gate via 146 on the X-Y plane.

Referring to FIG. 43, each of the first and second channel features 114A, 116A has a first end 1141, 1161 and a second end 1142, 1162 which are opposite to each other in the Y direction, and which are proximate to the first and second end regions 1394, 1395 of the gate feature 1390, respectively. In some embodiments, each of the first and second ends 1141, 1142, 1161, 1162 is spaced apart from a corresponding one of the first and second end regions 1394, 1395 by a minimum distance (E3, E4, E5, E6) ranging from about 3 nm to about 20 nm. If the distance (E3, E4, E5, E6) is too small (for example, less than about 3 nm), a threshold voltage of each of the first and second semiconductor devices 300, 400 (see FIG. 45) may be difficult to be controlled by the gate feature 1390. If the distance (E3, E4, E5, E6) is too large (for example, greater than about 20 nm), a fringing capacitance may be unduly increased.

Referring to FIG. 43, a first proximate one of the first channel features 114A of the first semiconductor units 132 is most proximate to the second channel features 116A of the second semiconductor units 133, and a second proximate one of the second channel features 116A of the second semiconductor units 133 is most proximate to the first channel features 114A of the first semiconductor units 132. In some embodiments, the first proximate one of the first channel features 114A is spaced apart from the second proximate one of the second channel features 116A by a distance (D3) ranging from about 10 nm to about 50 nm.

Referring to FIG. 1B and the examples illustrated in FIGS. 37 and 44, the method 1100 proceeds to step 1121, where two second fillers 207 are respectively formed in the two second cutout portions 206 shown in FIG. 40. FIG. 44 is a view similar to that of FIG. 40 in accordance with some embodiments, but illustrating the structure after step 1121, and the structure shown in FIG. 37 is substantially not changed after step 1121.

In some embodiments, since materials suitable for the second fillers 207 are similar to those for the first filler 143, details thereof are omitted for the sake of brevity. Other suitable materials for the second fillers 207 are within the contemplated scope of the present disclosure. In some embodiments, each of the second fillers 207 may have a thickness (T5) ranging from about 30 nm to about 200 nm. The thickness of the second fillers 207 depends on the number of the channel features (i.e., the first and second channel features 114A, 116A). When the number of the channel features in total is greater than six, the thickness (T5) of the second fillers 207 may be greater than about 200 nm.

In some embodiments, step 1121 may include (i) filling a dielectric material for forming the second fillers 207 in the second cutout portions 206 using for example, but not limited to, ALD, CVD, or other suitable techniques, and (ii) removing an excess of the dielectric material for forming the second fillers 207 to expose the ILD feature 205A using CMP, or other suitable techniques, thereby obtaining the second fillers 207.

Referring to FIG. 1B and the examples illustrated in FIGS. 44 and 45, the method 1100 proceeds to step 1122, where two second contact features 208 are formed in the ILD feature 205A to be electrically connected to the first source/drain features 127, respectively. FIG. 45 is a view similar to that of FIG. 37 in accordance with some embodiments, but illustrating the structure after step 1122, and the structure shown in FIG. 44 is substantially not changed after step 1122.

In some embodiments, step 1122 may include (i) forming a patterned mask layer (not shown) on the structure obtained after step 1121 using a lithography process, (ii) performing an etching process (for example, but not limited to, dry etching, wet etching, or a combination thereof) through the patterned mask layer to form openings (not shown), each extending through the ILD feature 205A to expose a corresponding one of the first source/drain features 127, (iii) filling a conductive material for forming the second contact features 208 in the openings using for example, but not limited to, ALD, CVD, plating, or other suitable techniques, and (iv) removing an excess of the conductive material for forming the second contact features 208 to expose the third ILD feature 205A using CMP or other suitable techniques, thereby obtaining the second contact features 208. Since suitable conductive materials for the second contact features 208 are similar to those for the first contact features 144, details thereof are omitted for the sake of brevity.

After step 1122, as shown in FIG. 45, a semiconductor structure 500 including the first semiconductor device 300 and the second semiconductor device 400 stacked on the first semiconductor device 300 is thus formed. The first and second semiconductor devices 300, 400 respectively include the first and second semiconductor units 132, 133, and share the same gate feature 1390. In other words, the first and second semiconductor devices 300, 400 may be controlled by the same gate feature 1390.

In some embodiments, the semiconductor structure 500 may further include a plurality of interconnect layers each including an inter-metal dielectric (IMD) feature (not shown) in which electrically conductive elements (not shown, for example, metal contacts, metal lines and/or metal vias) are formed so as to permit the first and second semiconductor devices 300, 400 to be electrically connected to external circuits through the electrically conductive elements. In some embodiments, the interconnect layers may be formed by a dual damascene process, a single damascene process, or other suitable back-end-of-line (BEOL) techniques.

In some embodiments, some steps in the method 1100 may be modified, replaced, or eliminated without departure from the spirit and scope of the present disclosure. For example, the method 1100 may be used for forming a semiconductor structure including one of the first and second semiconductor devices 300, 400, where each of the first and second semiconductor devices 300, 400 is configured as a GAA FET. Furthermore, the method 1100 may be used for forming a semiconductor structure including a FinFET, or a plurality of FinFETs stacked on each other. Additionally, the method 1100 may be used for forming a plurality of the semiconductor structures 500 electrically connected to each other so as to be configured as a memory cell. In some alternative embodiments, other suitable methods may also be applied for forming the semiconductor structure 500.

In the method 1100, the electrically conductive capping feature 140A is in direct contact with the first surface 1391 of the gate feature 1390 which is distal from the semiconductor substrate 109 (see FIGS. 36 and 40), and the gate material layer 139 is patterned from the proximate portion 139A which is proximate to the semiconductor substrate 109 (see FIGS. 36 and 38). In some alternative embodiments, as described below, the electrically conductive capping feature 140A may be in direct contact with the second surface 1392 of the gate feature 1390 which is proximate to the semiconductor substrate 109, and the gate material layer 139 may be patterned from the distal portion 139B which is distal from the semiconductor substrate 109. It is noted that similar numerals from the above-mentioned embodiments are used where appropriate, with some construction differences being indicated with different numerals.

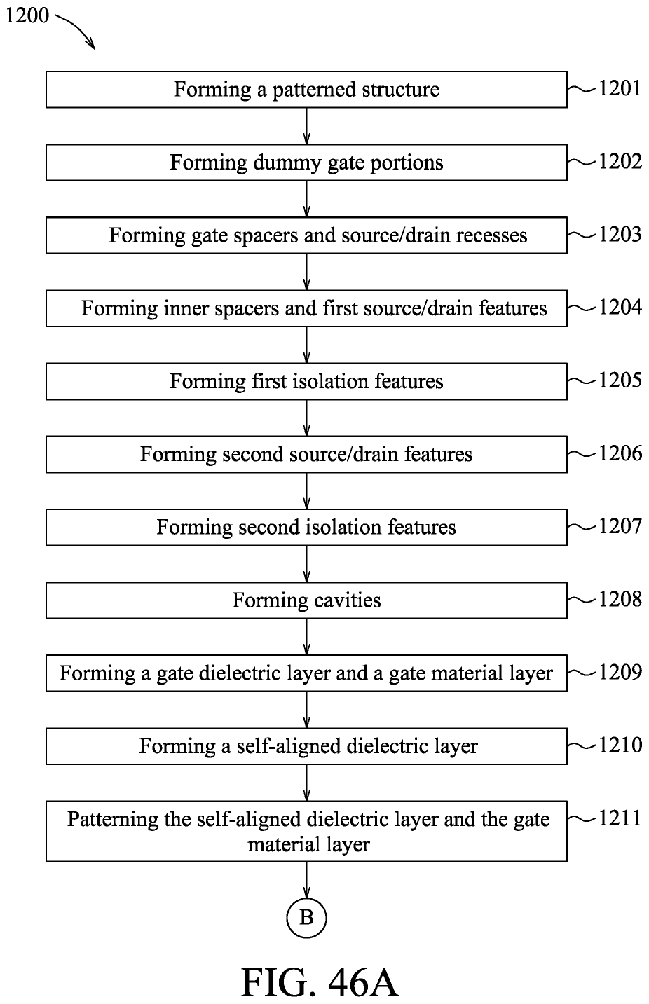

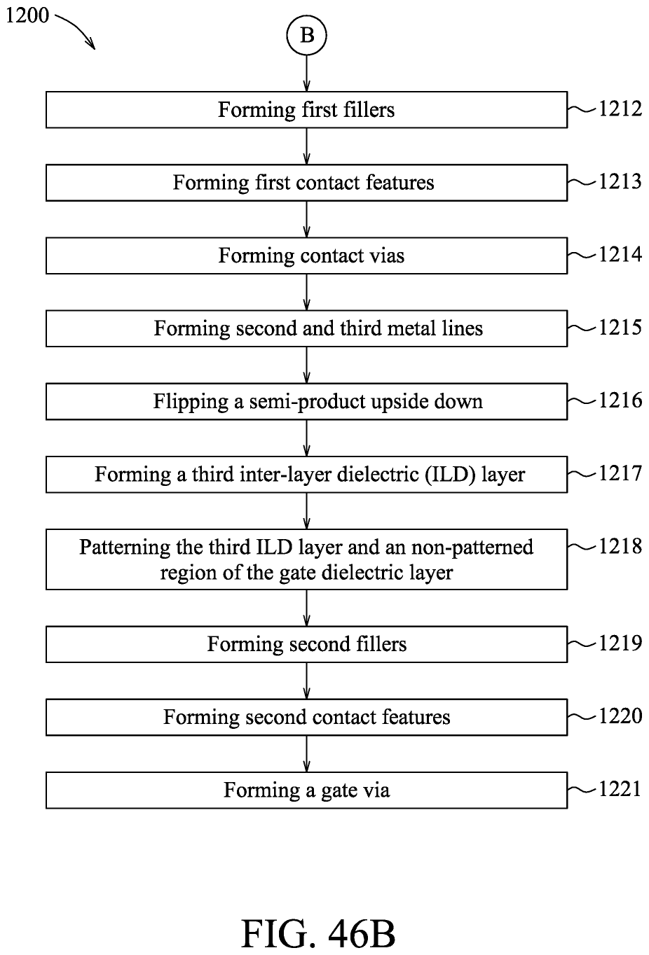

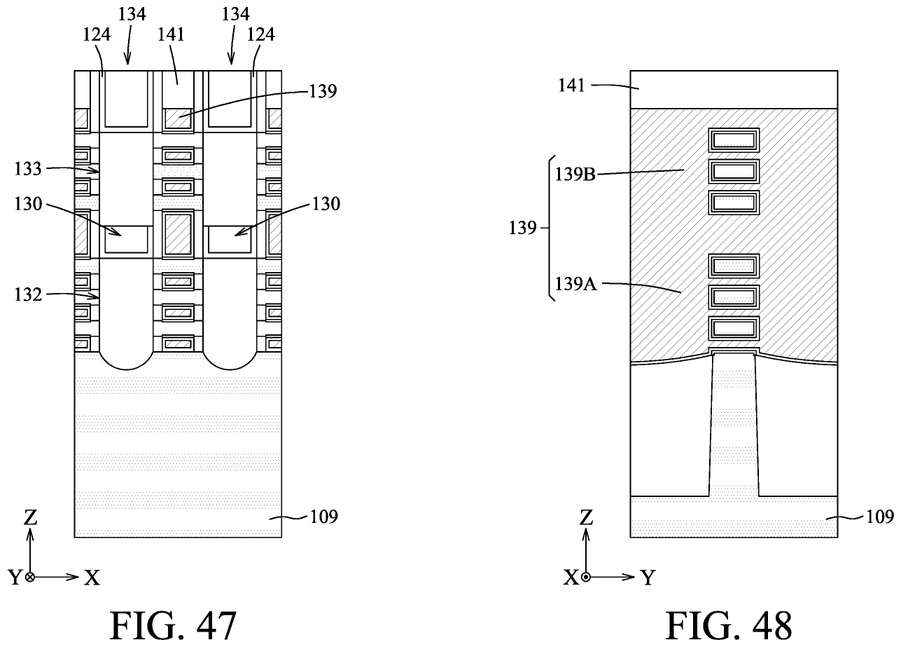

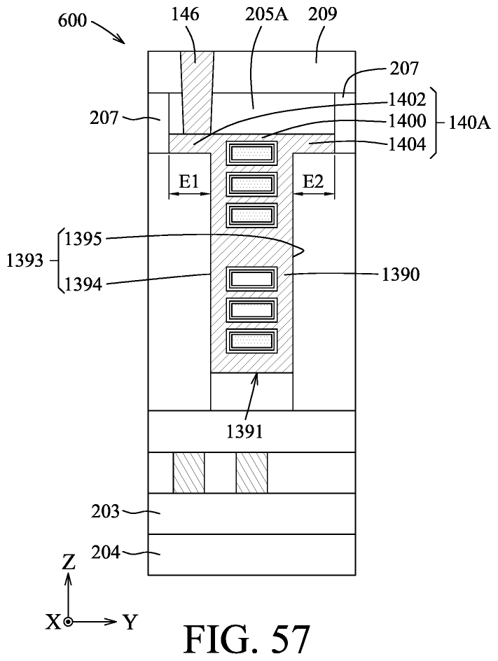

FIGS. 46A and 46B are flow diagrams illustrating a method 1200 for manufacturing a semiconductor structure (for example, a semiconductor structure 600 shown in FIGS. 56 and 57) in accordance with some embodiments. FIGS. 47 to 57 illustrate schematic views of the intermediate stages of the method 1200 in accordance with some embodiments. The method 1200 includes steps 1201 to 1221, where steps 1201 to 1209 are similar to steps 1101 to 1109 described above with reference to FIGS. 2 to 21, and thus details thereof are omitted for the sake of brevity.

Referring to FIG. 46A and the examples illustrated in FIGS. 47 and 48, the method 1200 proceeds to step 1210, where the self-aligned dielectric layer 141 is formed on the distal portion 139B of the gate material layer 139. FIGS. 47 and 48 are views similar to those of FIGS. 20 and 21, respectively, in accordance with some embodiments, but illustrating the structures after step 1210.

In some embodiments, step 1210 may include (i) depositing the fifth dielectric material for forming the self-aligned dielectric layer 141 on the structure shown in FIGS. 20 and 21 using a blanket deposition process, such as, but not limited to, CVD, ALD, or other suitable deposition techniques, and (ii) performing a planarization process, for example, but not limited to, CMP, or other suitable processes, to expose the second isolation features 134, thereby obtaining the self-aligned dielectric layer 141.

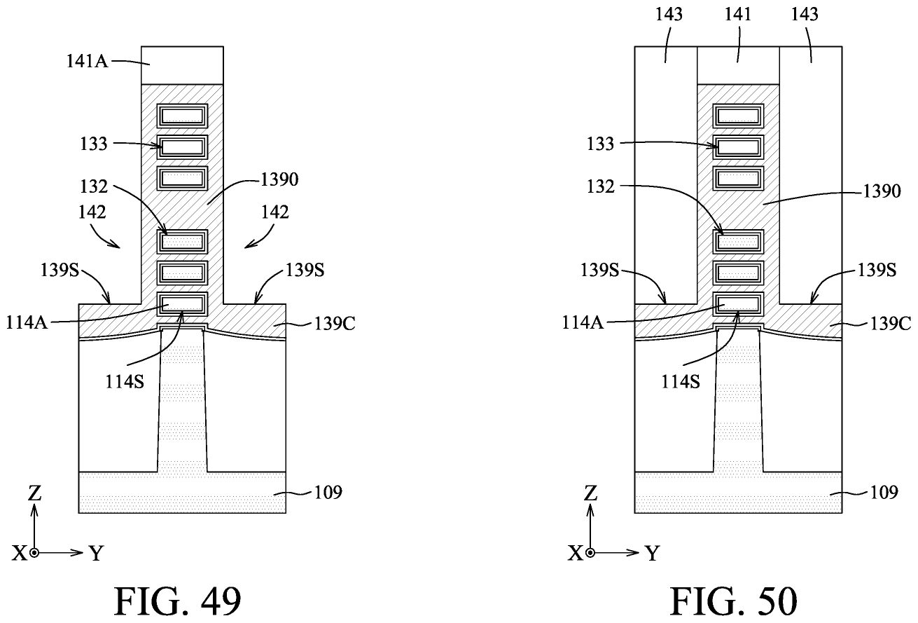

Referring to FIG. 46A and the examples illustrated in FIGS. 47 and 49, the method 1200 proceeds to step 1211, where the self-aligned dielectric layer 141 (see FIG. 48) is patterned into the self-aligned dielectric feature 141A, and the gate material layer 139 (see FIG. 48) is patterned from the distal portion 139B to form the gate feature 1390 which is distal from the semiconductor substrate 109, and an non-patterned region 139C which is a region of the proximate portion 139A and which is proximate to the semiconductor substrate 109. FIG. 49 is a view similar to that of FIG. 48 in accordance with some embodiments, but illustrating the structure after step 1211, and the structure shown in FIG. 47 is substantially not changed after step 1211.

After step 1211, the two first cutout portions 142, which are spaced apart from each other in the Y direction, are formed at two opposite sides of each of the first and second semiconductor units 132, 133 (see also FIG. 47). In some embodiments, each of the first cutout portions 142 extends oppositely in the X direction into the first and second isolation features 130, 134 which is formed at two opposite sides of the gate material layer 139 (see FIG. 47).

In some embodiments, the non-patterned region 139C has two surfaces 139S at two opposite sides of the gate feature 1390 and exposed from the two first cutout portions 142, respectively. A proximate one of the first channel features 114A of the first semiconductor unit 132 is most proximate to the semiconductor substrate 109, and has a lower surface 114S proximate to the semiconductor substrate 109. In some embodiments, the exposed surfaces 139S of the non-patterned region 139C are located coincident with a second reference surface which is spaced apart from the semiconductor substrate 109 by a distance greater than a distance between the semiconductor substrate 109 and the lower surface 114S of the proximate one of the first channel features 114A.

In some embodiments, step 1211 may include (i) forming a photoresist on the structure obtained after step 1210, (ii) performing a lithography process to form a patterned photoresist, and (iii) performing an etching process to etch the self-aligned dielectric layer 141, the gate material layer 139, the gate dielectric layer 138 and the first and second isolation features 130, 134 (see FIG. 47) through the patterned photoresist using, for example, dry etching, wet etching, other suitable etching techniques, or combinations thereof, to a level where the second reference surface is reached, thereby obtaining the first cutout portions 142.

Referring to FIG. 46B and the examples illustrated in FIGS. 47 and 50, the method 1200 proceeds to step 1212, where two first fillers 143 are respectively formed in the two first cutout portions 142 shown in FIG. 49. FIG. 50 is a view similar to that of FIG. 49 in accordance with some embodiments, but illustrating the structure after step 1212, and the structure shown in FIG. 48 is substantially not changed after step 1212.

In some embodiments, step 1212 may be performed in a manner similar to that of step 1113 as describe above with reference to FIG. 28, and thus details thereof are omitted for the sake of brevity.

Afterwards, the method 1200 proceeds to steps 1213 and 1214. Since steps 1213 and 1214 are similar to steps 1114 and 1116 described above with reference to FIGS. 29 and 32, and thus details thereof are omitted for the sake of brevity.

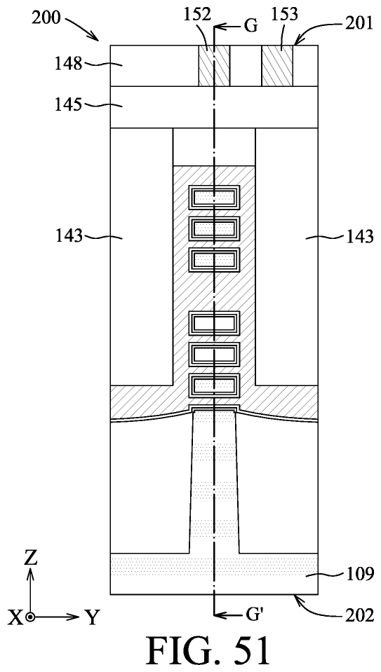

Referring to FIG. 46B and the example illustrated in FIG. 51, the method 1200 proceeds to step 1215, where the second and third metal lines 152, 153 are formed in the second ILD layer 148 which is formed on the first ILD layer 145. In FIG. 51, the first metal line 151 shown in FIG. 34 is not formed, and the second and third metal lines 152, 153 are respectively electrically connected to the contact vias 147. FIG. 51 is view similar to that of FIG. 50 in accordance with some embodiments, but illustrating the structure after step 1215. A schematic sectional view taken along line G-G′ of FIG. 51 in accordance with some embodiments is similar to the schematic sectional view shown in FIG. 33 except that the electrically conductive capping feature 140A is absent.

In some embodiments, step 1215 may be performed in a manner similar to that of step 1117 except that two of the grooves are formed, and that the second and third metal lines 152, 153 are formed in the two grooves, respectively, and thus details of suitable materials and/or processes for forming the second and third metal lines 152, 153 are omitted for the sake of brevity.

After step 1215, the semi-product 200 as shown in FIG. 51 is thus formed. The semi-product 200 has the front-side surface 201 opposite to the semiconductor substrate 109, and the backside surface 202 opposite to the front-side surface 201.

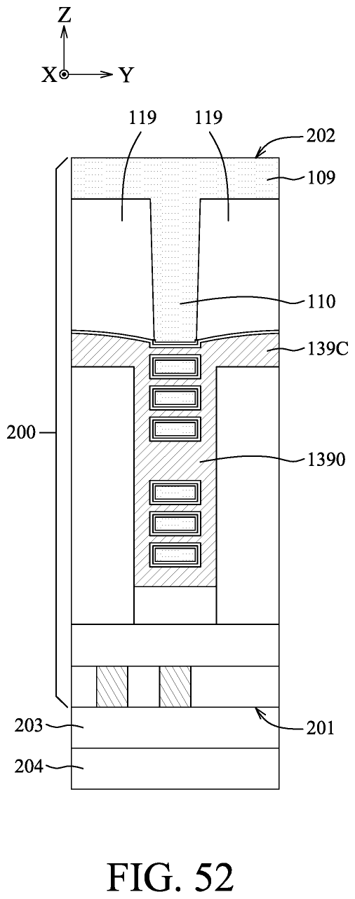

Referring to FIG. 46B and the example illustrated in FIG. 52, the method 1200 proceeds to step 1216, where the semi-product 200 is flipped upside down through the carrier substrate 204. FIG. 52 is view similar to that of FIG. 51 in accordance with some embodiments, but illustrating the structure after step 1216. Since step 1216 is similar to step 1118 described above with reference to FIGS. 35 and 36, and thus details thereof are omitted for the sake of brevity.

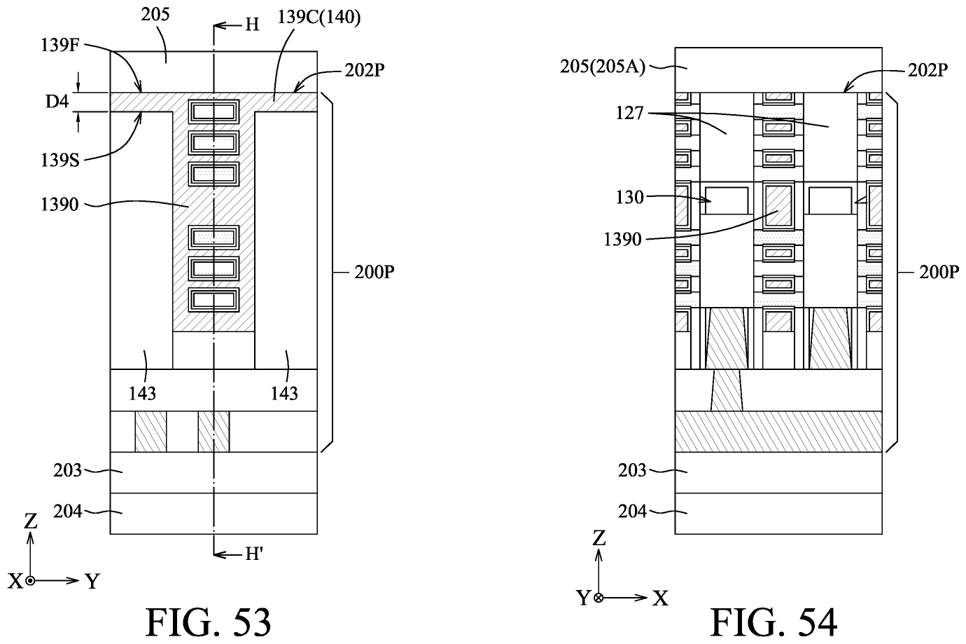

Referring to FIG. 46B and the examples illustrated in FIGS. 53 and 54, the method 1200 proceeds to step 1217, where the third ILD layer 205 is formed. FIG. 53 is a view similar to that of FIG. 52 in accordance with some embodiments, but illustrating the structure after step 1217. FIG. 54 is a sectional view taken along line H-H′ of FIG. 53.

In some embodiments, step 1217 may include (i) removing the semiconductor substrate 109 from the backside surface 202 using a planarization process (for example, but not limited to, CMP) and/or an etching process to expose the non-patterned region 139C (see FIG. 52) and the first source/drain features 127, such that the backside-polished semi-product 200P having the backside surface 202P opposite to the carrier substrate 204 is formed, and such that the non-patterned region 139C is polished to have a flat surface 139F opposite to the exposed surfaces 139S, and (ii) forming the third ILD layer 205 on the backside surface 202P of the backside-polished semi-product 200P by CVD, ALD, or other suitable deposition techniques. In some embodiments, the lower fin portion 110 and the isolation portions 119 shown in FIG. 52 are removed after step 1217.

In some embodiments, as shown in FIG. 53, the polished region 139C may serve as the electrically conductive capping layer 140. That is, in some embodiments, the electrically conductive capping layer 140 is a portion of the gate material layer 139 shown in FIG. 48 and includes a material the same as that of the gate feature 1390. In some embodiments, the flat surface 139F may be spaced apart from the exposed surfaces 139S by a distance (D4) ranging from about 3 nm to about 20 nm. If the distance (D4) is too small (for example, less than about 3 nm), a threshold voltage of each of the first and second semiconductor devices 300, 400 (see FIG. 56) may be difficult to be controlled by the gate feature 1390. If the distance (D4) is too large (for example, greater than about 20 nm), a fringing capacitance may be unduly increased.

In some embodiments, the electrically conductive capping layer 140 may further include an additional electrically conducive capping element (not shown) formed between the polished region 139C and the third ILD layer 205 so as to reduce an electrical resistance between the gate feature 1390 and the gate via 146 (see FIG. 57). Suitable materials for the additional electrically conducive capping element are similar to those for the electrically conducive capping layer 140 as describe above with reference to FIGS. 22 and 23, and thus details thereof are omitted for the sake of brevity. In some embodiments, the additional electrically conducive capping element may be selectively formed on the polished region 139C before formation of the third ILD layer 205 using CVD, ALD, or other suitable deposition techniques.

In some embodiments, an interface between the electrically conductive capping layer 140 and the third ILD layer 205 is located coincident with a third reference surface, and interfaces between the electrically conductive capping layer 140 and the first fillers 143 are located coincident with a fourth reference surface. In some embodiments, the third reference surface is spaced apart from the fourth reference surface by a distance (D4) ranging from about 3 nm to about 20 nm.

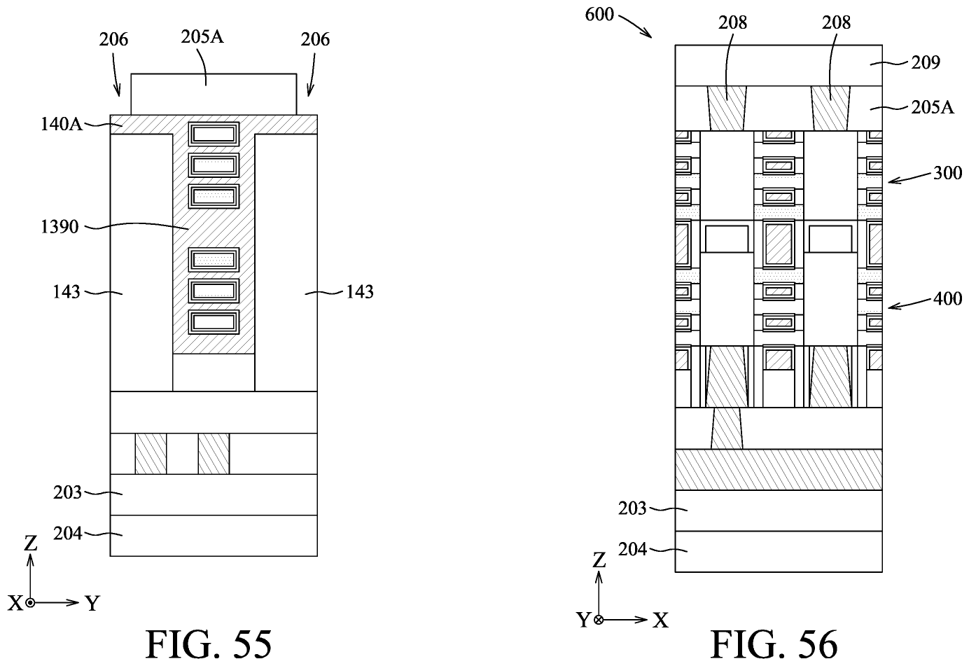

Referring to FIG. 46B and the examples illustrated in FIGS. 54 and 55, the method 1200 proceeds to step 1218, where the third ILD layer 205 and the electrically conductive capping layer 140 (see FIG. 53) are respectively patterned into the ILD feature 205A and the electrically conductive capping feature 140A. After step 1218, the two second cutout portions 206 are spaced apart from each other in the Y direction, and are formed at two opposite sides of a stack of the ILD feature 205A and the electrically conductive capping feature 140A.

In some embodiments, each of the second cutout portions 206 extends in the X direction in the third ILD feature 205A. In some embodiments, a portion of each of the second cutout portions 206 is formed in the first isolation features 130 which are formed at two opposite sides of the gate feature 1390.

In some embodiments, step 1218 may include (i) forming a photoresist on the structure obtained after step 1217, (ii) performing a lithography process to form a patterned photoresist, and (iii) performing an etching process to etch the third ILD layer 205, the electrically conductive capping layer 140 (see FIG. 53) and a portion of the first second isolation features 130 through the patterned photoresist using, for example, dry etching, wet etching, other suitable etching techniques, or combinations thereof, thereby obtaining the second cutout portions 206.

Afterwards, the method 1200 proceeds to steps 1219 and 1220. Since steps 1219 and 1220 are similar to steps 1121 and 1122 described above with reference to FIGS. 44 and 45, and thus details thereof are omitted for the sake of brevity.

Referring to FIG. 46B and the examples illustrated in FIGS. 56 and 57, the method 1200 proceeds to step 1221, where the gate via 146 is formed. FIGS. 56 and 57 are views similar to those of FIGS. 54 and 55, respectively, in accordance with some embodiments, but illustrating the structures after step 1221.

In some embodiments, step 1221 may include (i) forming a fourth ILD layer 209 on the structure obtained after step 1220 using a blanket deposition process, for example, but not limited to, CVD, MLD or other suitable techniques, (ii) forming a patterned mask (not shown) on the fourth ILD layer 209 using a lithography process, (iii) performing an etching process (for example, but not limited to, dry etching, wet etching, or a combination thereof) through the patterned mask to form the gate via opening (not shown) which extends through the fourth ILD layer 209 and the ILD feature 205A to expose the electrically conductive capping feature 140A, (iv) filling the gate via opening with a material for forming the gate via 146 using, for example, ALD, CVD, plating, or other suitable techniques, and (v) removing an excess of the material for forming the gate via 146 and removing the patterned mask to expose the fourth ILD layer 209, thereby obtaining the gate via 146.

For the semiconductor structure 600 manufactured by the method 1200, (i) the main portion 1400 of the electrically conductive capping feature 140A is in direct contact with the second surface 1392 of the gate feature 1390, (ii) the first extending portion 1402 of the electrically conductive capping feature 140A extends from the main portion 1400 beyond the first end region 1394 of the interconnect surface 1393 of the gate feature 1390 by a distance (E1), and (iii) the gate via 146 is in direct contact with the first extending portion 1402 of the electrically conductive capping feature 140A from a side distal from the carrier substrate 204.

In some embodiments, the electrically conductive capping feature 140A further includes the second extending portion 1404 extending from the main portion 1400 beyond the second end region 1395 of the interconnect surface 1393 of the gate feature 1390 by a distance (E2). In some embodiments, each of the distances (E1, E2) is not greater than about 20 nm. In some embodiments, at least one of the distances (E1, E2) is greater than about 2 nm.

In some embodiments, the gate feature 1390 and the electrically conductive capping feature 140A may have variations in configuration (e.g., E1 to E6, L1, L2) which may be similar to those described above with reference to FIGS. 40 to 43, and thus details thereof are omitted for the sake of brevity.

In some embodiments, some steps in the method 1200 may be modified, replaced, or eliminated without departure from the spirit and scope of the present disclosure. In some alternative embodiments, other suitable methods may also be applied for forming the semiconductor structure 600.

In this disclosure, the semiconductor structure is provided to include two of the semiconductor devices stacked on each other, and thus may occupy a relatively small area in a single chip. Furthermore, the semiconductor structure includes the gate feature having a relatively small area as viewed in a Y-Z plane, which effectively reduces a gate to source/drain fringing capacitance, thereby increasing switching speed of the semiconductor devices. Although the gate feature has a reduced dimension, with the introduction of the electrically conductive capping feature in direct contact with the gate feature and extending beyond the interconnect surface of the gate feature, the gate via (VG) may also be configured to be staggered from the contact vias (VD) of one of the semiconductor devices, thereby increasing feasibility of circuit design. Additionally, the electrically conductive capping feature can be formed proximate to one of the semiconductor devices and distal from the other one of the semiconductor devices, or vice versa. Therefore, the methods for making the semiconductor structure provided in this disclosure enable implementation of various circuit design.

In accordance with some embodiments of the present disclosure, a semiconductor structure includes two source/drain features spaced apart from each other, at least one channel feature disposed between the two source/drain features, a gate dielectric layer disposed on the at least one channel feature, a gate feature, and an electrically conductive capping feature. The gate feature is disposed on the gate dielectric layer and has a first surface, a second surface which is opposite to the first surface, and an interconnect surface which interconnects the first and second surfaces. The electrically conductive capping feature is in direct contact with one of the first and second surfaces of the gate feature, and extends beyond the interconnect surface of the gate feature.

In accordance with some embodiments of the present disclosure, the source/drain features are spaced apart from each other in an X direction, the gate feature has a first length in a Y direction transverse to the X direction, and the electrically conductive capping feature has a second length in the Y direction which is greater than the first length.

In accordance with some embodiments of the present disclosure, the semiconductor structure further includes two contact features respectively disposed on the two source/drain features. Each of the two contact features has a contact surface in contact with a corresponding one of the source/drain features, and an opposite surface opposite to the contact surface. An interface between the electrically conductive capping feature and the gate feature is located coincident with a reference surface which is located between the contact surface and the opposite surface of each of the contact features.

In accordance with some embodiments of the present disclosure, the electrically conductive capping feature has a thickness ranging from 2 nm to 15 nm.

In accordance with some embodiments of the present disclosure, the electrically conductive capping feature includes a main portion and a first extending portion. The main portion is in direct contact with the one of the first and second surfaces of the gate feature, and has a first end and a second end opposite to the first end. The first extending portion extends from the first end of the main portion beyond the interconnect surface of the gate feature.

In accordance with some embodiments of the present disclosure, the electrically conductive capping feature further includes a second extending portion which extends from the second end of the main portion beyond the interconnect surface of the gate feature. Each of the first and second extending portions extends beyond the interconnect surface by a distance not greater than 20 nm, and at least one of the first and second extending portions extends beyond the interconnect surface by a distance greater than 2 nm.

In accordance with some embodiments of the present disclosure, the semiconductor structure includes a plurality of the channel features separated from each other, and the gate feature is disposed to surround and to be separated from the channel features through the gate dielectric layer.

In accordance with some embodiments of the present disclosure, a semiconductor structure includes a first semiconductor unit, a second semiconductor unit, a gate feature, a gate dielectric layer and an electrically conductive capping feature. Each of the first and second semiconductor units includes two source/drain features spaced apart from each other, and a plurality of channel features spaced apart from each other. Each of the channel features extends between the two source/drain features. The gate feature is disposed to surround the channel features of the first and second semiconductor units, and has a first surface, a second surface which is opposite to the first surface, and an interconnect surface which interconnects the first and second surfaces. The gate dielectric layer is disposed to separate the gate feature from the channel features of the first and second semiconductor units. The electrically conductive capping feature is in direct contact with one of the first and second surfaces of the gate feature, and extends beyond the interconnect surface of the gate feature.

In accordance with some embodiments of the present disclosure, the source/drain features are spaced apart from each other in an X direction. The channel features of the semiconductor units are spaced apart from each other in a Z direction transverse to the X direction. The first and second surfaces of the gate feature are opposite to each other in the Z direction. The gate feature has a first length in a Y direction transverse to both the X and Z directions. The electrically conductive capping feature has a second length in the Y direction which is greater than the first length.

In accordance with some embodiments of the present disclosure, the first and second semiconductor units are disposed distal from and proximate to the electrically conductive capping feature, respectively. The semiconductor structure further includes two first contact features respectively disposed on the source/drain features of the second semiconductor units, and two second contact features respectively disposed on the source/drain features of the first semiconductor units. Each of the first and second contact features has a contact surface in contact with a corresponding one of the source/drain features of the first and second semiconductor units, and an opposite surface opposite to the contact surface. An interface between the electrically conductive capping feature and the gate feature is located coincident with a reference surface which is located between the contact surface and the opposite surface of each of the first contact features.

In accordance with some embodiments of the present disclosure, the source/drain features are spaced apart from each other in an X direction. The interconnect surface of the gate feature has a first end region and a second end region opposite to each other in a Y direction transverse to the X direction. The first and second surfaces of the gate feature are opposite to each other in a Z direction transverse to both the X and Y directions. The electrically conductive capping feature includes a main portion which is in direct contact with the one of the first and second surfaces of the gate feature, and a first extending portion which extends from the main portion beyond the first end region by a distance ranging from 2 nm to 20 nm.

In accordance with some embodiments of the present disclosure, the semiconductor structure further includes two contact vias respectively disposed on the two first contact features, and a gate via which is in direct contact with the first extending portion, and which is staggered from the two contact vias in both the X and Y directions.

In accordance with some embodiments of the present disclosure, each of the channel features has a first end, and a second end which are opposite to each other in the Y direction, and which are proximate to the first and second end regions of the gate feature, respectively. Each of the first and second ends is spaced apart from a corresponding one of the first and second end regions by a minimum distance ranging from 3 nm to 20 nm.

In accordance with some embodiments of the present disclosure, a first proximate one of the channel features of the first semiconductor units is most proximate to the channel features of the second semiconductor units. A second proximate one of the channel features of the second semiconductor units is most proximate to the channel features of the first semiconductor units. The first proximate one of the channel features is spaced apart from the second proximate one of the channel features by a distance ranging from 10 nm to 50 nm.

In accordance with some embodiments of the present disclosure, a method for manufacturing a semiconductor structure includes forming a first semiconductor unit and a second semiconductor unit on a semiconductor substrate, each of the first and second semiconductor units including two source/drain features spaced apart from each other, and a plurality of channel features spaced apart from each other, each of the channel features extending between the two source/drain features; forming a gate dielectric layer to cover the channel features of the first and second semiconductor units; and forming a gate feature and an electrically conductive capping feature such that the gate feature surrounds and is separated from the channel features of the first and second semiconductor units through the gate dielectric layer and such that the electrically conductive capping feature is in direct contact with one of a first surface and a second surface of the gate feature and extends beyond an interconnect surface of the gate feature, the first and second surfaces of the gate feature being distal from and proximate to the semiconductor substrate, respectively, the interconnect surface of the gate feature interconnecting the first and second surfaces.

In accordance with some embodiments of the present disclosure, forming the gate feature and the electrically conductive capping feature includes forming a gate material layer on the gate dielectric layer such that the gate material layer surrounds and is separated from the channel features of the first and second semiconductor units through the gate dielectric layer, the gate material layer having a distal portion and a proximate portion which are distal from and proximate to the semiconductor substrate, respectively; forming the electrically conductive capping feature on one of the distal and proximate portions; and patterning the gate material layer into the gate feature such that the distal portion is patterned to have the first surface of the gate feature and the proximate portion is patterned to have the second surface of the gate feature.

In accordance with some embodiments of the present disclosure, the electrically conductive capping feature is in direct contact with the first surface of the gate feature.

In accordance with some embodiments of the present disclosure, before pattering the gate material layer, the method further includes removing the semiconductor substrate to expose the proximate portion of the gate material layer so as to permit the gate material layer to be patterned from the proximate portion.

In accordance with some embodiments of the present disclosure, the electrically conductive capping feature is in direct contact with the second surface of the gate feature.

In accordance with some embodiments of the present disclosure, patterning the gate material layer is performed from the distal portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
two source/drain features spaced apart from each other;
at least one channel feature disposed between the two source/drain features;
a gate dielectric layer disposed on the at least one channel feature;
a gate feature disposed on the gate dielectric layer and having a first surface, a second surface which is opposite to the first surface, and an interconnect surface which interconnects the first and second surfaces; and
an electrically conductive capping feature which is in direct contact with one of the first and second surfaces of the gate feature and which extends beyond the interconnect surface of the gate feature.

2. The semiconductor structure of claim 1, wherein:
the source/drain features are spaced apart from each other in an X direction;
the gate feature has a first length in a Y direction transverse to the X direction; and
the electrically conductive capping feature has a second length in the Y direction which is greater than the first length.

3. The semiconductor structure of claim 1, further comprising two contact features respectively disposed on the two source/drain features, each of the two contact features having a contact surface in contact with a corresponding one of the source/drain features, and an opposite surface opposite to the contact surface, an interface between the electrically conductive capping feature and the gate feature being located coincident with a reference surface which is located between the contact surface and the opposite surface of each of the contact features.

4. The semiconductor structure of claim 1, wherein the electrically conductive capping feature has a thickness ranging from 2 nm to 15 nm.

5. The semiconductor structure of claim 1, wherein the electrically conductive capping feature includes:
a main portion which is in direct contact with the one of the first and second surfaces of the gate feature, and which has a first end and a second end opposite to the first end; and
a first extending portion which extends from the first end of the main portion beyond the interconnect surface of the gate feature.

6. The semiconductor structure of claim 5, wherein:
the electrically conductive capping feature further includes a second extending portion which extends from the second end of the main portion beyond the interconnect surface of the gate feature;
each of the first and second extending portions extends beyond the interconnect surface by a distance not greater than 20 nm; and
at least one of the first and second extending portions extends beyond the interconnect surface by a distance greater than 2 nm.

7. The semiconductor structure of claim 1, wherein the semiconductor structure includes a plurality of the channel features separated from each other, the gate feature being disposed to surround and to be separated from the channel features through the gate dielectric layer.

8. A semiconductor structure, comprising:
a first semiconductor unit and a second semiconductor unit, each including
two source/drain features spaced apart from each other, and
a plurality of channel features spaced apart from each other, each of the channel features extending between the two source/drain features;
a gate feature disposed to surround the channel features of the first and second semiconductor units, and having a first surface, a second surface which is opposite to the first surface, and an interconnect surface which interconnects the first and second surfaces;
a gate dielectric layer disposed to separate the gate feature from the channel features of the first and second semiconductor units; and
an electrically conductive capping feature which is in direct contact with one of the first and second surfaces of the gate feature, and which extends beyond the interconnect surface of the gate feature.

9. The semiconductor structure of claim 8, wherein:
the source/drain features are spaced apart from each other in an X direction;
the channel features of the semiconductor units are spaced apart from each other in a Z direction transverse to the X direction;
the first and second surfaces of the gate feature are opposite to each other in the Z direction;
the gate feature has a first length in a Y direction transverse to both the X and Z directions; and
the electrically conductive capping feature has a second length in the Y direction which is greater than the first length.

10. The semiconductor structure of claim 8, wherein:
the first and second semiconductor units are disposed distal from and proximate to the electrically conductive capping feature, respectively;
the semiconductor structure further comprises two first contact features respectively disposed on the source/drain features of the second semiconductor units, and two second contact features respectively disposed on the source/drain features of the first semiconductor units, each of the first and second contact features having a contact surface in contact with a corresponding one of the source/drain features of the first and second semiconductor units, and an opposite surface opposite to the contact surface; and
an interface between the electrically conductive capping feature and the gate feature is located coincident with a reference surface which is located between the contact surface and the opposite surface of each of the first contact features.

11. The semiconductor structure of claim 8, wherein:
the source/drain features are spaced apart from each other in an X direction;
the interconnect surface of the gate feature has a first end region and a second end region opposite to each other in a Y direction transverse to the X direction;
the first and second surfaces of the gate feature are opposite to each other in a Z direction transverse to both the X and Y directions; and
the electrically conductive capping feature includes
a main portion which is in direct contact with the one of the first and second surfaces of the gate feature, and
a first extending portion which extends from the main portion beyond the first end region by a distance ranging from 2 nm to 20 nm.

12. The semiconductor structure of claim 11, further comprising:
two contact vias respectively disposed on the two first contact features; and
a gate via which is in direct contact with the first extending portion, and which is staggered from the two contact vias in both the X and Y directions.

13. The semiconductor structure of claim 11, wherein each of the channel features has a first end and a second end which are opposite to each other in the Y direction, and which are proximate to the first and second end regions of the gate feature, respectively, each of the first and second ends being spaced apart from a corresponding one of the first and second end regions by a minimum distance ranging from 3 nm to 20 nm.

14. The semiconductor structure of claim 8, wherein:
a first proximate one of the channel features of the first semiconductor units is most proximate to the channel features of the second semiconductor units;
a second proximate one of the channel features of the second semiconductor units is most proximate to the channel features of the first semiconductor units; and
the first proximate one of the channel features is spaced apart from the second proximate one of the channel features by a distance ranging from 10 nm to 50 nm.

15. A method for manufacturing a semiconductor structure, comprising:
forming a first semiconductor unit and a second semiconductor unit on a semiconductor substrate, each of the first and second semiconductor units including
two source/drain features spaced apart from each other, and
a plurality of channel features spaced apart from each other, each of the channel features extending between the two source/drain features;
forming a gate dielectric layer to cover the channel features of the first and second semiconductor units; and
forming a gate feature and an electrically conductive capping feature such that the gate feature surrounds and is separated from the channel features of the first and second semiconductor units through the gate dielectric layer and such that the electrically conductive capping feature is in direct contact with one of a first surface and a second surface of the gate feature and extends beyond an interconnect surface of the gate feature, the first and second surfaces of the gate feature being distal from and proximate to the semiconductor substrate, respectively, the interconnect surface of the gate feature interconnecting the first and second surfaces.

16. The method of claim 15, wherein forming the gate feature and the electrically conductive capping feature includes:
forming a gate material layer on the gate dielectric layer such that the gate material layer surrounds and is separated from the channel features of the first and second semiconductor units through the gate dielectric layer, the gate material layer having a distal portion and a proximate portion which are distal from and proximate to the semiconductor substrate, respectively;
forming the electrically conductive capping feature on one of the distal and proximate portions; and
patterning the gate material layer into the gate feature such that the distal portion is patterned to have the first surface of the gate feature and the proximate portion is patterned to have the second surface of the gate feature.

17. The method of claim 16, wherein the electrically conductive capping feature is in direct contact with the first surface of the gate feature.

18. The method of claim 17, before pattering the gate material layer, further comprising:
removing the semiconductor substrate to expose the proximate portion of the gate material layer so as to permit the gate material layer to be patterned from the proximate portion.

19. The method of claim 16, wherein the electrically conductive capping feature is in direct contact with the second surface of the gate feature.

20. The method of claim 19, wherein patterning the gate material layer is performed from the distal portion.
